(19) United States
(12) Patent Application Publication
(10) Pub. No.: US 2024/0110279 A1
(43) Pub. Date: Apr. 4, 2024

(54) ATOMIC LAYER DEPOSITION WITH MULTIPLE UNIFORMLY HEATED CHARGE VOLUMES

(71) Applicant: LAM RESEARCH CORPORATION, Fremont, CA (US)

(72) Inventors: Nitin KADAM, Dharwad (IN); Aaron Blake MILLER, West Linn, OR (US); Naveen PATIL, Hubli (IN); Panya WONGSENAKHUM, Fremont, CA (US); Gorun BUTAIL, Fremont, CA (US); Shruti THOMBARE, sUNNYVALE, CA (US)

(21) Appl. No.: 18/265,825

(22) PCT Filed: Dec. 14, 2021
(86) PCT No.: PCT/US2021/072901

§ 371 Date: Jun. 7, 2023

(30) Foreign Application Priority Data
Dec. 19, 2020 (IN) 202041055393

(51) Int. Cl. C23C 16/455; C23C 16/46

(52) U.S. Cl. CPC C23C 16/45544; C23C 16/45527; C23C 16/46

(57) ABSTRACT

Multiple charge volumes (CVs) are used to supply a reactant and an inert gas at each processing chamber to perform atomic layer deposition (ALD) on substrates. A series of pulses of the reactant can be supplied at a high flow rate from two CVs during a dose step, which extends dose time. The inert gas can be supplied at an equal starting pressure from first and second CVs at first and second purge steps. A heated pulse valve manifold (PVM) minimizes temperature variations of process gases supplied from the PVM to respective processing chamber during ALD. The PVM preheats the process gases before the process gases enter the respective CVs in the PVM. The PVM includes additional supplemental heaters above and below the CVs to maintain the temperature of the process gases within the CVs. The PVM can be rapidly cooled before performing maintenance, which reduces downtime.

### CROSS-REFERENCE TO RELATED APPLICATIONS

This application claims the benefit of Indian Application No. 202041055393, filed on Dec. 19, 2020. The entire disclosure of the above application is incorporated herein by reference.

### FIELD

The present disclosure relates generally to substrate processing systems and more particularly to atomic layer deposition with multiple uniformly heated charge volumes.

### BACKGROUND

The background description provided here is for the purpose of generally presenting the context of the disclosure. Work of the presently named inventors, to the extent it is described in this background section, as well as aspects of the description that may not otherwise qualify as prior art at the time of filing, are neither expressly nor impliedly admitted as prior art against the present disclosure.

Atomic Layer Deposition (ALD) is a thin-film deposition method that sequentially performs a gaseous chemical process to deposit a thin film on a surface of a material (e.g., a surface of a substrate such as a semiconductor wafer). Most ALD reactions use at least two chemicals called precursors (reactants) that react with the surface of the material one precursor at a time in a sequential, self-limiting manner. Through repeated exposure to separate precursors, a thin film is gradually deposited on the surface of the material. A thermal ALD (T-ALD) process is typically performed in a heated processing chamber. The processing chamber is maintained at a sub-atmospheric pressure using a vacuum pump and a controlled flow of an inert gas. The substrate to be coated with a film is placed in the processing chamber and is allowed to equilibrate with the temperature of the processing chamber before starting the ALD process.

### SUMMARY

A system comprises first and second canisters configured to supply a reactant to a processing chamber during a dose step of an atomic layer deposition (ALD) sequence. The system comprises first and second valves configured to connect the first and second canisters to the processing chamber, respectively. The system comprises a controller configured to supply a first pulse of the reactant from the first canister to the processing chamber during the dose step of the ALD sequence by activating the first valve. The controller is configured to supply a second pulse of the reactant from the second canister to the processing chamber during the dose step of the ALD sequence by activating the second valve.

In other features, the system further comprises a third canister configured to supply a purge gas to the processing chamber during a purge step of the ALD sequence. The system further comprises a third valve configured to connect the third canister to the processing chamber. The controller is configured to supply a third pulse of the purge gas from the third canister to the processing chamber during the purge step of the ALD sequence by activating the third valve. The third pulse is supplied after supplying the second pulse of the reactant in the dose step.

In still other features, a system comprises first and second canisters configured to supply a purge gas to a processing chamber during purge steps of an atomic layer deposition (ALD) sequence. The system comprises first and second valves configured to connect the first and second canisters to the processing chamber, respectively. The system comprises a controller configured to supply a first pulse of the purge gas from the first canister to the processing chamber during a first purge step of the ALD sequence by activating the first valve. The controller is supply a second pulse of the purge gas from the second canister to the processing chamber during a second purge step of the ALD sequence by activating the second valve. The second purge step follows the first purge step in the ALD sequence.

In other features, the system further comprises a third canister configured to supply a second gas to the processing chamber during a dose step of the ALD sequence, the second gas including a reactant or a precursor. The system further comprises a third valve configured to connect the third canister to the processing chamber. The controller is configured to supply a third pulse of the second gas from the third canister to the processing chamber during the dose step of the ALD sequence by activating the third valve. The third pulse is supplied after supplying the first pulse of the purge gas in the first purge step and before supplying the second pulse of the purge gas in the second purge step.

In still other features, a system comprises first and second canisters configured to supply a reactant to a processing chamber during a dose step of an atomic layer deposition (ALD) sequence. The system comprises a third canister configured to supply a purge gas to the processing chamber during a purge step of the ALD sequence. The system comprises first, second, and third valves configured to connect the first, second, and third canisters to the processing chamber, respectively. The system comprises a controller configured to perform the following. a) Supply a first pulse of the reactant from the first canister to the processing chamber during the dose step of the ALD sequence by activating the first valve. b) Supply a second pulse of the reactant from the second canister to the processing chamber during the dose step of the ALD sequence by activating the second valve after the first pulse. c) Supply a third pulse of the purge gas from the third canister to the processing chamber during the purge step of the ALD sequence by activating the third valve following the second pulse of the reactant in the dose step. d) Repeat a), b), and c) N times, where N is a positive integer.

In other features, the system further comprises a fourth canister configured to supply a precursor to the processing chamber during a second dose step of the ALD sequence. The system further comprises a fifth canister configured to supply the purge gas to the processing chamber during a second purge step of the ALD sequence. The system further comprises fourth and fifth valves configured to connect the fourth and fifth canisters to the processing chamber, respectively. The controller is further configured to perform the following. e) Supply a fourth pulse of the precursor from the fourth canister to the processing chamber during the second dose step of the ALD sequence by activating the fourth valve following d). f) Supply a fifth pulse of the purge gas from the fifth canister to the processing chamber during the second purge step of the ALD sequence by activating the fifth valve following e).

In other features, the controller is further configured to repeat f) M times, where M is a positive integer.

In still other features, a system comprises first and second canisters configured to supply a reactant to a processing chamber during a first dose step of an atomic layer deposition (ALD) sequence. The system comprises a third canister configured to supply a precursor to the processing chamber during a second dose step of the ALD sequence. The system comprises fourth and fifth canisters configured to supply a purge gas to the processing chamber during purge steps of the ALD sequence. The system comprises first, second, third, fourth, and fifth valves configured to connect the first, second, third, fourth, and fifth canisters to the processing chamber, respectively.

The system comprises a controller configured to perform the following. a) Supply a first pulse of the reactant from the first canister to the processing chamber during the first dose step of the ALD sequence by activating the first valve. b) Supply a second pulse of the reactant from the second canister to the processing chamber during the first dose step of the ALD sequence by activating the second valve after the first pulse. c) Supply a third pulse of the purge gas from the fourth canister to the processing chamber during a first purge step of the ALD sequence by activating the fourth valve following the second pulse of the reactant in the first dose step. d) Supply a fourth pulse of the precursor from the third canister to the processing chamber during the second dose step of the ALD sequence by activating the third valve following the third pulse of the purge gas in the first purge step. e) Supply a fifth pulse of the purge gas from the fifth canister to the processing chamber during a second purge step of the ALD sequence by activating the fifth valve following the fourth pulse of the precursor in the second dose step.

In other features, the controller is further configured to perform the following: f) Repeat a), b), and c) N times before performing d) and e). g) Perform d) and e) after f). Repeat g) M times, where M is a positive integer.

In still other features, a system comprises a plurality of gas lines arranged in slots in a metal plate, a first heater disposed adjacent to the slots in the metal plate, a plurality of canisters arranged on a base plate and connected to the gas lines, and a plurality of valves arranged on the base plate to connect the canisters to a showerhead of a processing chamber.

In another feature, the system further comprises a second heater attached to the base plate.

In another feature, the system further comprises a second heater arranged above the canisters.

In another feature, the system further comprises a layer of a thermally conducting material disposed between the second heater and the canisters.

In other features, the system further comprises a second heater attached to the base plate, a third heater arranged above the canisters, and a layer of a thermally conducting material disposed between the third heater and the canisters.

In other features, the canisters are of the same size and shape.

In other features, the system further comprises a second plurality of canisters connected between the gas lines and the plurality of canisters.

In other features, the second plurality of canisters have a different storage capacity than the plurality of canisters.

In other features, the system further comprises a second heater attached to the base plate, a third heater arranged above the plurality of canisters and the second plurality of canisters, and a layer of a thermally conducting material disposed between the third heater and the plurality of canisters and the second plurality of canisters.

In other features, the system further comprises a third plate that includes the second heater, that extends from the base plate, and that is connected to the metal plate. The second plurality of canisters is arranged on the extended portion of the third plate.

In still other features, an enclosure comprises the system and is mounted on the processing chamber. Inner walls of the enclosure include a second layer of a thermally insulating material.

In other features, the enclosure further comprises an inlet mounted to a first side of the enclosure to supply a pressurized gas into the enclosure, and an outlet on a second side of the enclosure to let out the pressurized gas from the enclosure.

In other features, the enclosure further comprises a distribution device mounted to the first side inside the enclosure that is aligned with the inlet to distribute the pressurized gas in the enclosure.

In another feature, the second heater is attached to a bottom of the base plate and is attached to a base panel of the enclosure using spacers.

In other features, the system further comprises at least two heat sensors disposed in each of the metal plate, the base plate, and a third plate comprising the third heater.

In other features, the base plate comprises gas channels that connect the gas lines, the canisters, and the valves.

In other features, the base plate comprises a plurality of bores in fluid communication with the valves and the processing chamber.

In other features, the system further comprises an adapter block connecting the base plate to a showerhead of the processing chamber and including a plurality of bores in fluid communication with the valves and the showerhead.

In other features, the base plate comprises a first plurality of bores in fluid communication with the valves. The system further comprises an adapter block connecting the base plate to a showerhead of the processing chamber and including a second plurality of bores in fluid communication with the first plurality of bores and the showerhead.

In other features, the metal plate is perpendicular to the base plate. The canisters and the valves are arranged in rows parallel to each other and the metal plate.

In other features, the system further comprises a third plate including the second heater attached to the base plate. The third plate extends from the base plate and is connected to the metal plate. The system further comprises a second plurality of canisters is arranged on the extended portion of the third plate and is connected to the gas lines and the plurality of canisters.

In other features, the system further comprises a third heater arranged above the plurality of canisters and the second plurality of canisters, and a layer of a thermally conducting material disposed between the third heater and the plurality of canisters and the second plurality of canisters.

In other features, the second plurality of canisters have a different storage capacity than the plurality of canisters.

In other features, the second plurality of canisters includes fewer number of canisters than the plurality of canisters.

Further areas of applicability of the present disclosure will become apparent from the detailed description, the claims and the drawings. The detailed description and specific examples are intended for purposes of illustration only and are not intended to limit the scope of the disclosure.

### BRIEF DESCRIPTION OF THE DRAWINGS

The present disclosure will become more fully understood from the detailed description and the accompanying drawings, wherein:

FIG. 1 shows an example of a substrate processing system comprising a plurality of processing chambers according to the present disclosure;

FIG. 2 shows an example of mass flow controllers (MFCs) and a pulse valve manifold (PVM) subsystem used with the processing chambers of the substrate processing system of FIG. 1;

FIG. 3 shows an example additional components associated with the processing chambers of FIG. 1;

FIG. 4A shows an example of an atomic layer deposition (ALD) sequence including multiple dose pulses used for processing substrates in the processing chambers of FIG. 1 according to the present disclosure;

FIG. 4B shows a method of processing a substrate in a processing chamber of the FIG. 1 using multiple dose pulses and using multiple charge volumes to supply an inert gas during purge steps of an ALD sequence according to the present disclosure;

FIG. 5 shows an example of a PVM subsystem used with the processing chambers of FIG. 1 according to the present disclosure;

FIG. 6 shows a side view of the PVM subsystem of FIG. 5 according to the present disclosure;

FIG. 7 shows a side view of charge volumes and valves of the PVM subsystem of FIG. 5 according to the present disclosure;

FIG. 8 shows a top view of the PVM subsystem of FIG. 5 according to the present disclosure;

FIG. 9 shows a longitudinal cross-section of a metal plate comprising gas lines used in the PVM subsystem of FIG. 5 according to the present disclosure;

FIGS. 10A and 10B show a transverse cross-section of the metal plate of FIG. 9 according to the present disclosure;

FIGS. 11A-11F show an example of a base plate of the PVM subsystem of FIG. 5 in further detail according to the present disclosure;

FIGS. 12A-12F show various views of an example of a heater plate of the PVM subsystem of FIG. 5 according to the present disclosure;

FIGS. 13A-13C show various views of an example of a thermal interface used with a top heater plate of the PVM subsystem of FIG. 5 according to the present disclosure;

FIGS. 14A-14C show an example of an enclosure that surrounds the PVM subsystem of FIG. 5 according to the present disclosure; and

FIGS. 15A-15C show an example of a cooling system used to cool the PVM subsystem of FIG. 5 according to the present disclosure.

In the drawings, reference numbers may be reused to identify similar and/or identical elements.

### DETAILED DESCRIPTION

A charge volume (CV) is a canister that receives a process gas supplied by a gas source. The CV temporarily stores the process gas and supplies the process gas to a processing chamber in a controlled manner as explained below. As the process gas is supplied (i.e., discharged) from the CV to the processing chamber, an additional volume of the process gas is supplied from the gas source to the CV to recharge the CV.

The present disclosure provides multiple manifolds and charge volumes for supplying a reactant and an inert gas at each processing chamber of a substrate processing system (also called a tool). For example, using two charge volumes of a reactant allows extending a dose time in an ALD sequence. The dose time can be extended because a series of pulses of the reactant can be supplied from the two charge volumes to a processing chamber at a high flow rate. During a dose step, a subsequent second pulse of a reactant from a second CV is supplied before a pressure of an immediately preceding first pulse of the reactant from a first CV decays (e.g., falls below a threshold; see FIG. 4A). By supplying the second pulse in quick succession in the same dose step, an average concentration of the reactant in the dose step can be maintained above a threshold for an extended period of time. Further, using two charge volumes of an inert gas ensures that the inert gas is supplied at an equal starting pressure at each purge step in the ALD sequence.

Additionally, the present disclosure provides a pulse valve manifold (PVM) for each processing chamber that minimizes temperature variations of process gases supplied from the PVM to a processing chamber during an ALD sequence. The PVM minimizes the temperature variations by preheating the process gases before the process gases enter the respective charge volumes in the PVM. The PVM is designed with sufficient inlet heater length to fully heat the process gases before the process gases enter the charge volumes. The PVM includes additional supplemental heaters above and below the charge volumes to maintain the temperature of the process gases within the charge volumes. A thermal interface is used between the supplemental heater and the charge volumes to ensure uniform heating of the charge volumes. The PVM design ensures that the process gases are delivered to the processing chamber at a relatively constant temperature. The PVM also includes a rapid cooling feature that rapidly cools the PVM and allows maintenance to be performed without waiting for the PVM to slowly cool by convection, which reduces downtime.

Typically, a gas delivery system for an ALD process uses one charge volume (CV) for one reactant. When dosing occurs, the reactant initially enters into a processing chamber at a relatively high flow rate due to a pressure difference between the charge volume and the processing chamber. However, the flow rate of the reactant quickly reduces and converges to a steady state flow rate of a mass flow controller (MFC) controlling the flow rate of the reactant. Some ALD processes have a relatively slow reaction rate and require a relatively long dose time if the flow rate of the reactant is not sufficient. Some ALD processes also need to purge byproducts relatively quickly to improve a film property such as resistivity. Accordingly, a purge gas needs to be supplied into the processing chamber not only at a proper time but also at a relatively high pressure at the start of each purge step, which can be difficult when a single CV is used to supply the purge gas during multiple purge steps.

The present disclosure solves the above problems by using multiple CVs of a reactant to input multiple dose pulses of the reactant at a high flow rate into the processing chamber in each dose cycle, which reduces dose time as compared to using a single CV. Additionally, using multiple CVs for supplying the purge gas in successive purge cycles ensures supply of the purge gas at a high flow rate at the beginning of each purge cycle, which quickly and effectively removes process byproducts. Accordingly, using multiple CVs together with their respective MFCs for supplying a reactant during a dose step can reduce dose time. Further, using multiple CVs with their respective MFCs for supplying a purge gas during multiple purge steps can ensure rapid and effective purging of the processing chamber in ALD processes.

In addition, the present disclosure provides a pulse valve manifold (PVM) subsystem for delivering uniformly heated and variable charge volumes to a substrate processing system during ALD processes. The substrate processing system typically comprises a plurality of processing chambers, each including a pedestal, a showerhead, a top plate, and a gas box arranged above the top plate. Process gases are supplied from the gas box to the processing chamber via the top plate and the showerhead. The PVM subsystem of the present disclosure delivers process gases to the processing chamber in a predefined sequence and at predetermined pressure and temperature during an ALD process.

The PVM subsystem comprises multiple CVs, actuating valves, a base plate, and connecting gas lines. The CVs store process gases as auxiliary storage. The CVs maintain a uniform and steady flow of the process gases into the processing chamber. The actuating valves facilitate flow of the process gases based on control signals from a system controller. The CVs and the actuating valves are mounted on a base plate. The PVM subsystem further comprises a heater arrangement that is used to attain elevated temperatures for the CVs, actuating valves, and the gas lines. The heater arrangement uses a thermal interface material that accommodates manufacturing variations in the CVs so that a heater can uniformly heat the process gases in the CVs as explained below in detail.

Currently, the PVM subsystem can hold only one set or family of chemically compatible gases. The current PVM subsystem cannot support chemically incompatible process gases. The current PVM subsystem also cannot support a solid precursor, which requires a heat source throughout a wetted flow path to maintain a predetermined temperature to keep the precursor in gaseous form. The PVM subsystem of the present disclosure supports a solid precursor and enhances the functionalities of the PVM subsystem to support process gases at elevated temperatures. As explained below in detail, the PVM subsystem of the present disclosure supports chemically incompatible process gases by using additional CVs that supply the purge gas separately for the incompatible gases so that the incompatible gases do not mix.

Furthermore, the current PVM subsystem can support CVs with a limited capacity (e.g., only 100 cc to 300 cc). The limited capacity of the CVs impacts the dose time (i.e., time required to deliver specific amount of a reactant to the processing chamber). The PVM subsystem uses dual CVs. Each dual CV includes two charge volumes of different capacities. The different capacities can be selected based on the dose time. For example, the capacity of each charge volume in the dual CV can range from 100 cc to 1000 cc. Other capacities can be used.

In addition, the PVM subsystem of the present disclosure comprises heating elements arranged at optimum locations to achieve uniform and steady temperatures across the entire PVM subsystem. For example, the PVM subsystem comprises three heating zones. A first heating zone is located at the base plate of the PVM subsystem. A second heating zone is located at the top of the PVM subsystem. The first and second heating zones supply heat to the CVs and the actuating valves. A thermal interface material is used to between the second heating zone and the top of the CVs to increase heat transfer and to accommodate tolerances of the heating elements and other components such as the CVs. A third heating zone heats the gas lines entering the PVM subsystem.

The heating zones are individually controlled to effectively supply a predetermined amount of heat and to maintain uniform temperature across the entire PVM subsystem. Unlike oven type heating, the mode of heat transfer to the CVs is conductive. Further, the heating zones are surrounded by an insulated enclosure to minimize heat loss. Additionally, air gaps between the heating zones and enclosure panels are used as insulation. In addition, two thermocouples are used in each heating zone to safeguard the PVM subsystem from overheating due to failure of one of the two thermocouples. The PVM subsystem also includes a forced convective cooling system (e.g., compressed dry air) that performs rapid cooling and allows performing preventive maintenance with less lead time, which reduces system downtime. These and other features of the present disclosure are described below in detail.

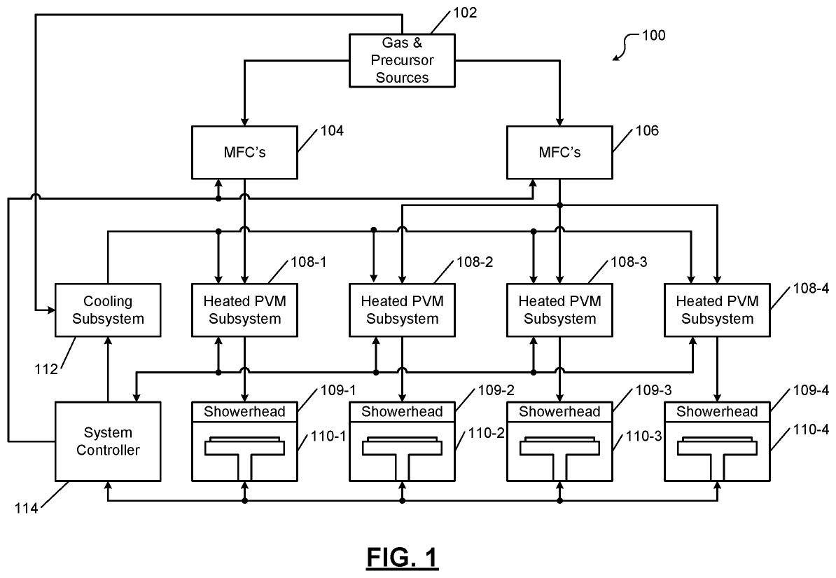

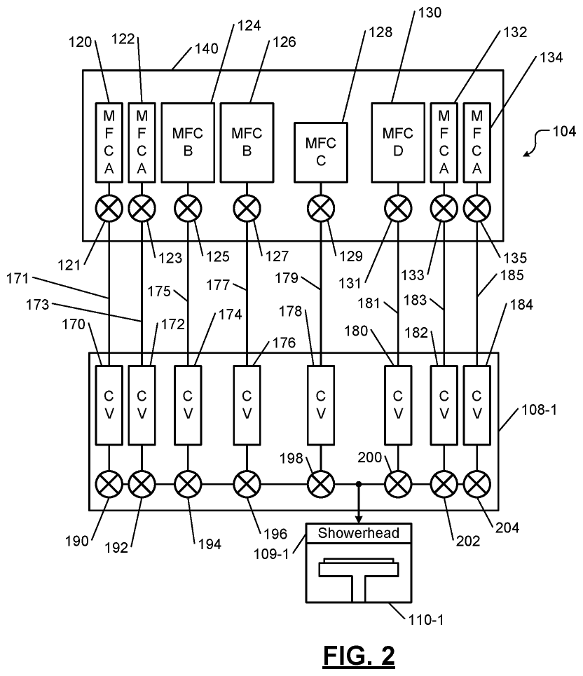

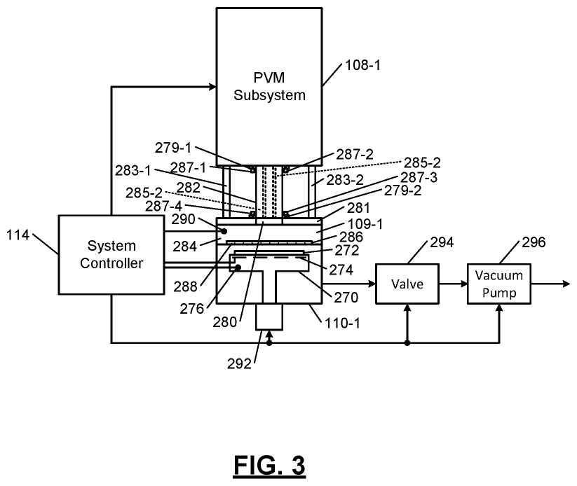

The present disclosure is organized as follows. An example of a substrate processing system according to the present disclosure is shown and described with reference to FIG. 1. Examples of mass flow controllers (MFCs) and PVM subsystems used in the substrate processing system are shown and described in further detail with reference to FIG. 2. Additional components associated with the processing chambers of the substrate processing system are shown and described with reference to FIG. 3. An example of an ALD sequence including multiple dose pulses according to the present disclosure is shown and described with reference to FIG. 4A. An example of a method of performing ALD using multiple dose pulses during a dose step and using multiple CVs to supply an inert gas during multiple purge steps is shown and described with reference to FIG. 4B.

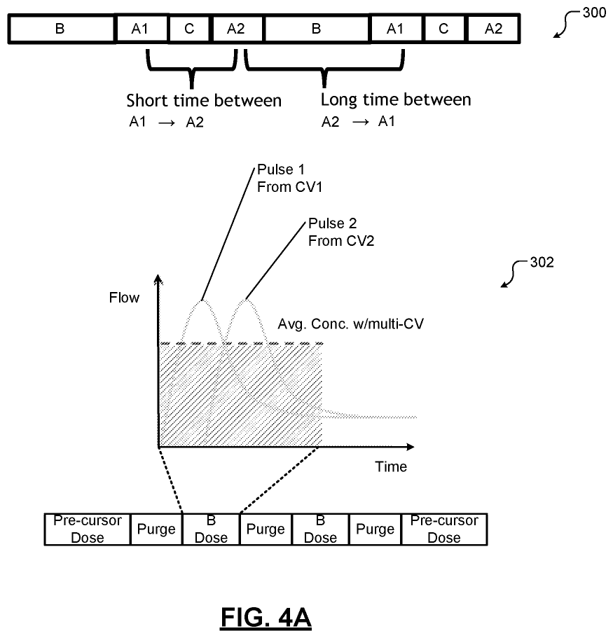

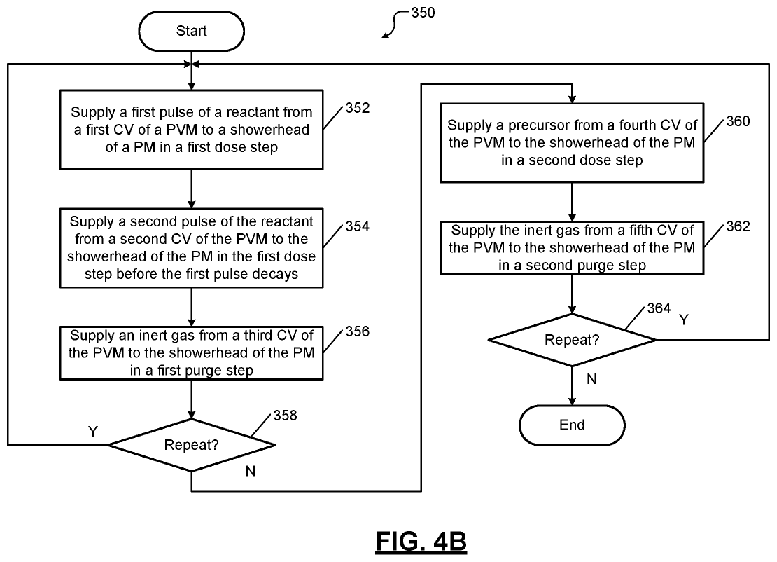

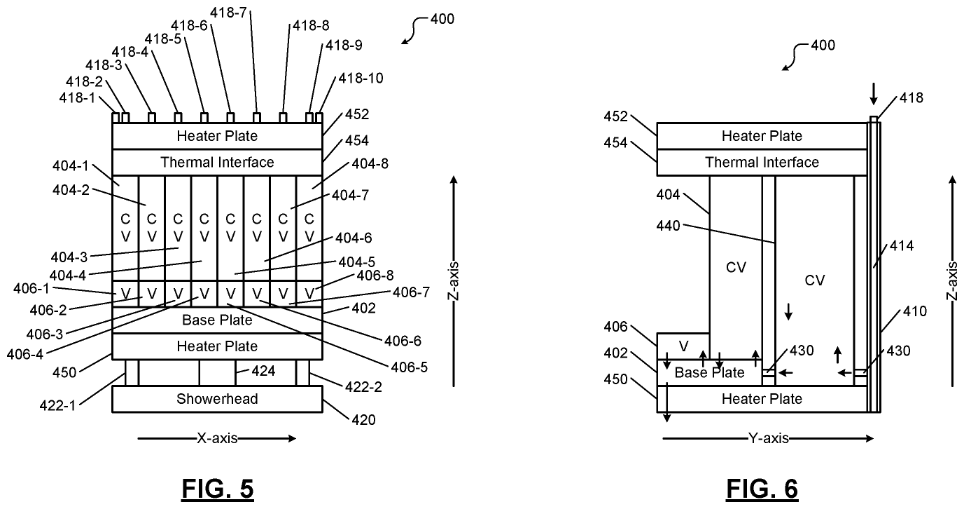

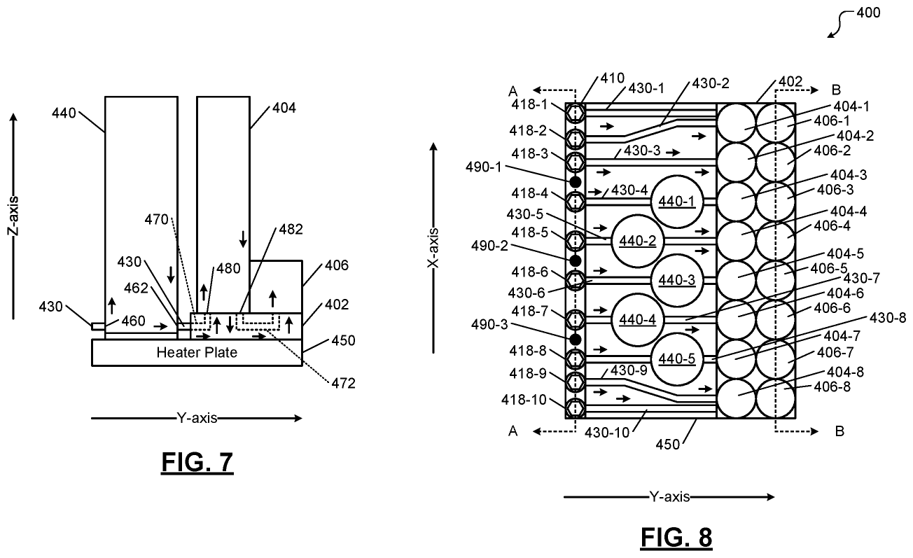

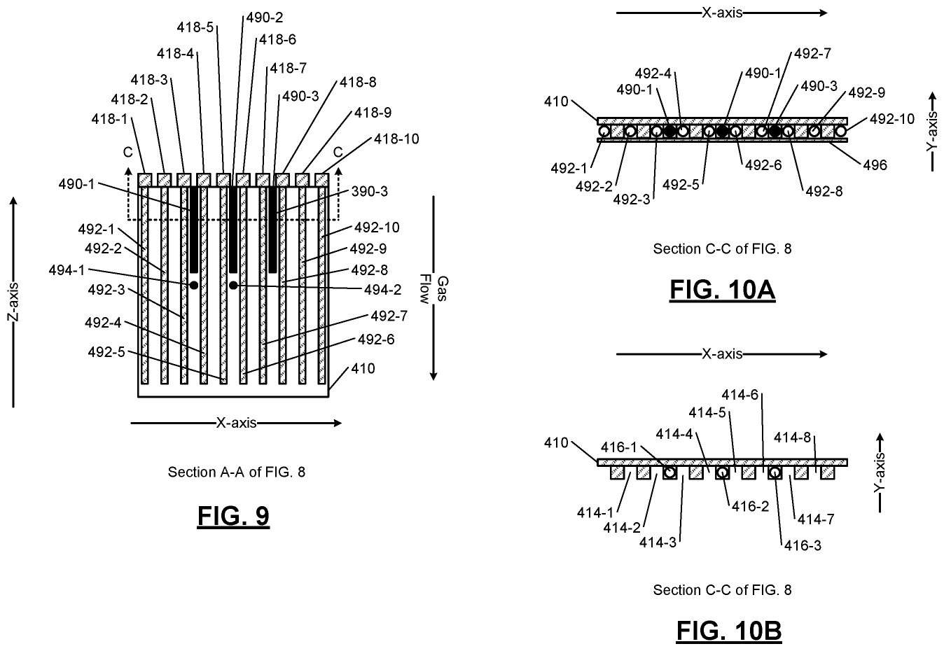

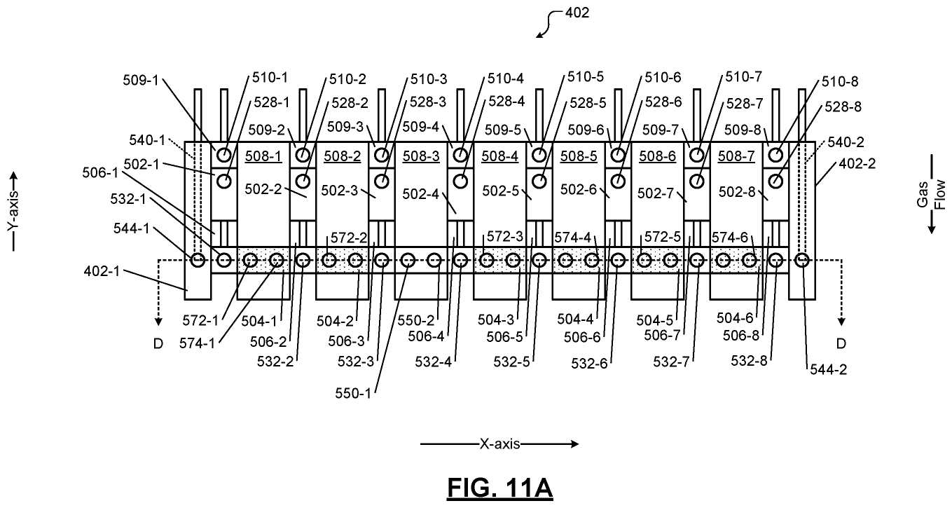

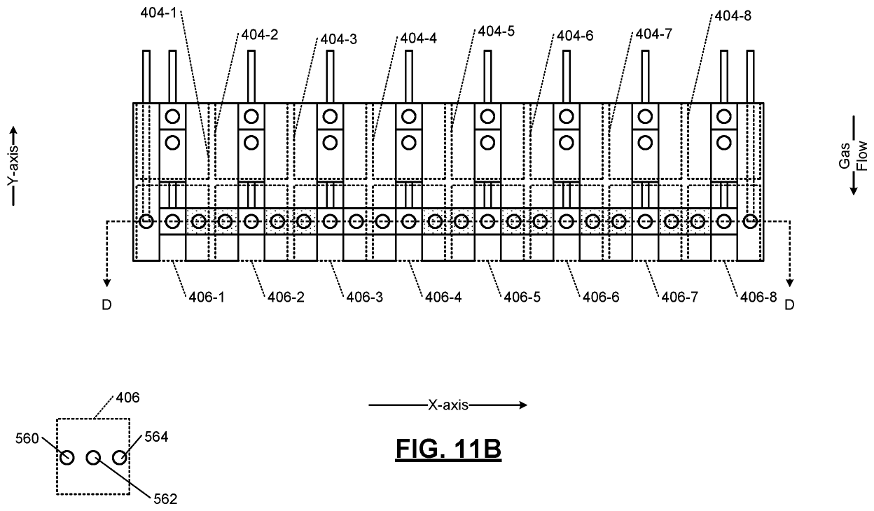

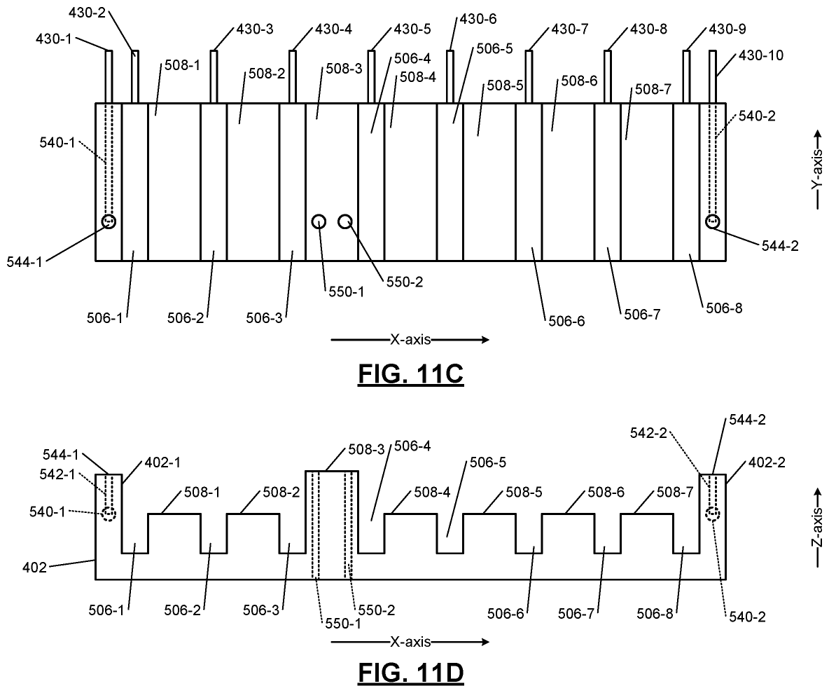

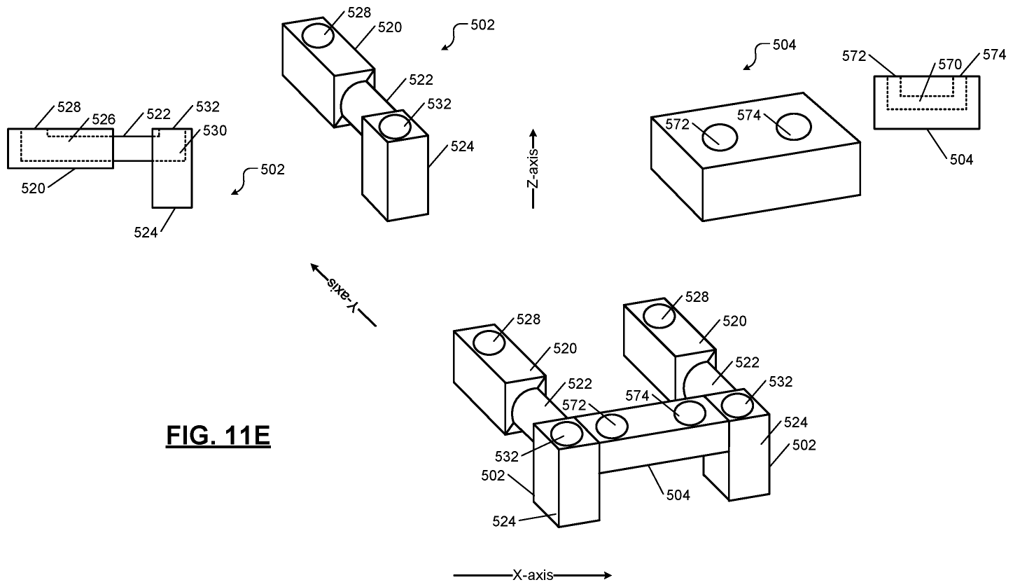

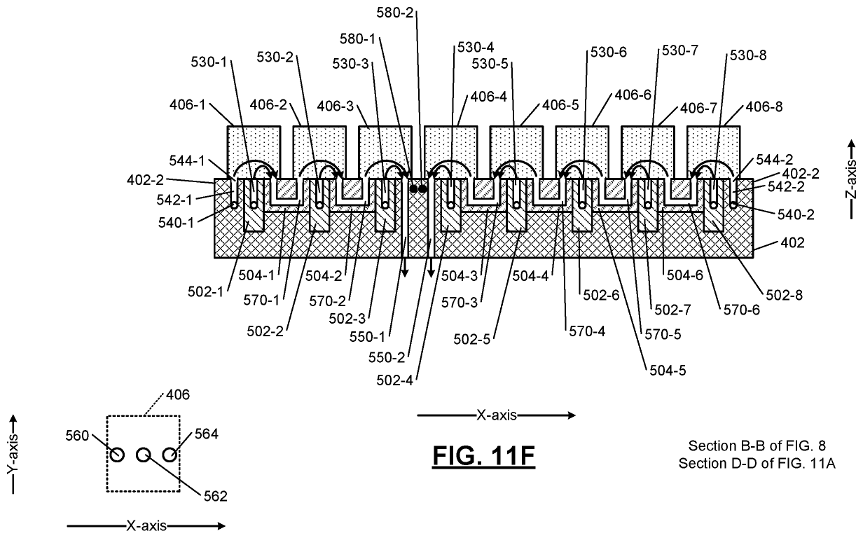

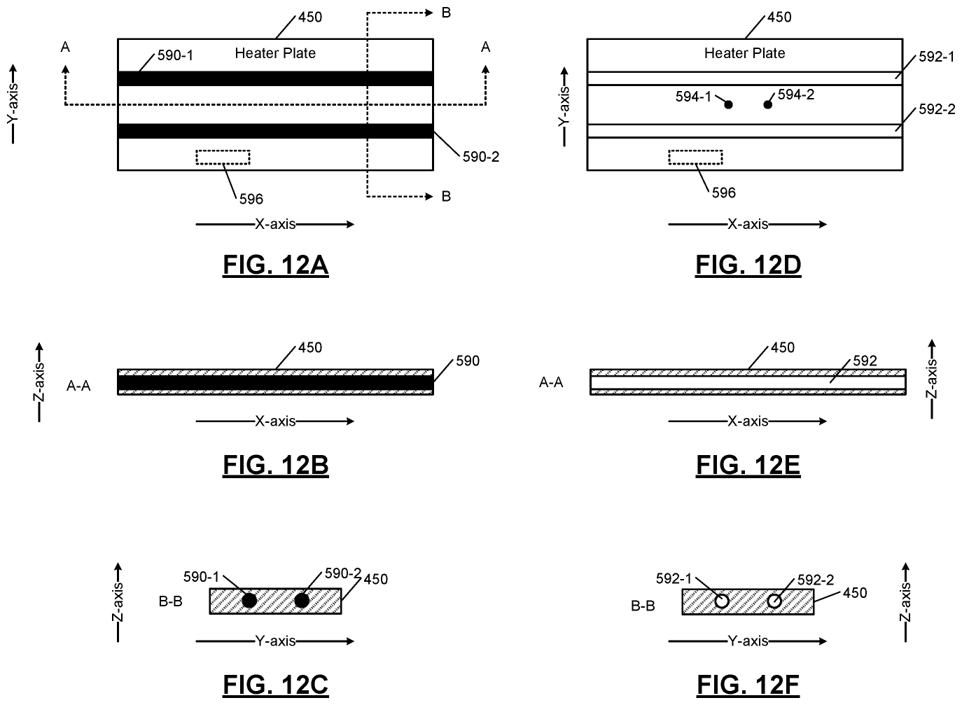

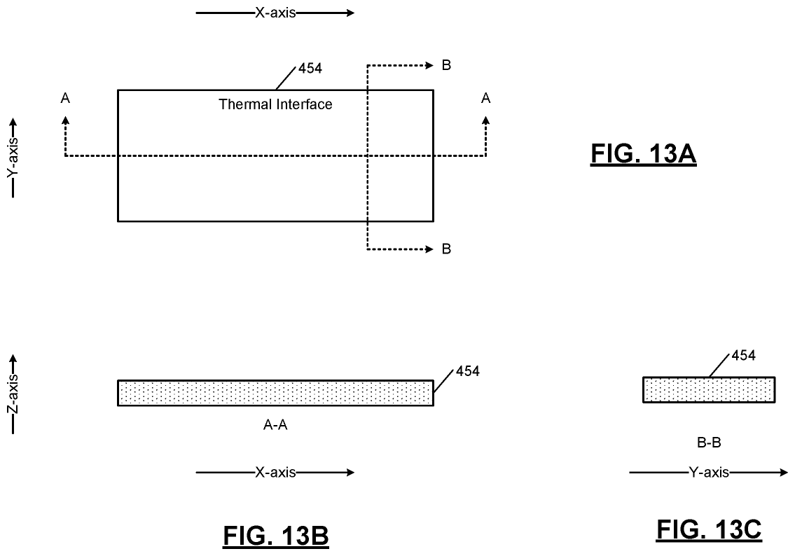

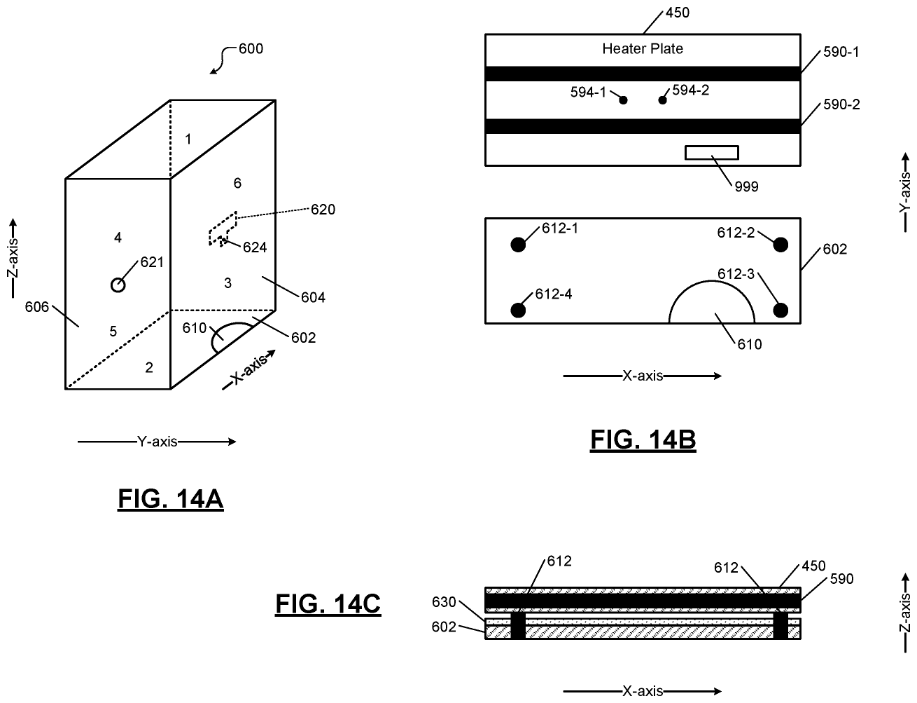

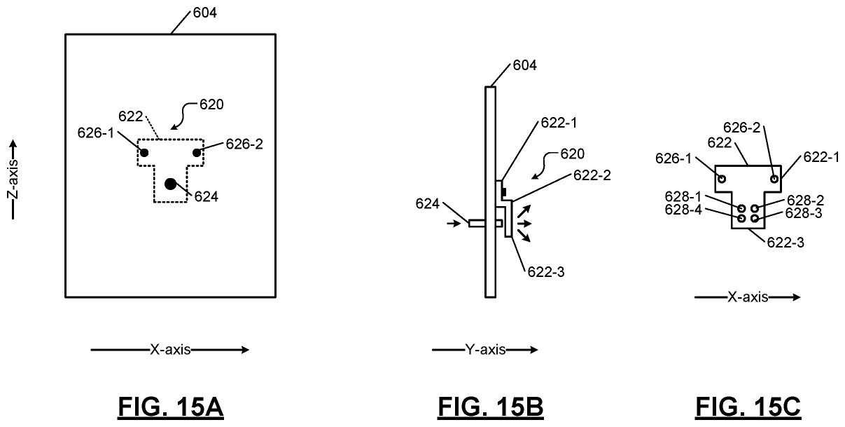

The PVM subsystem according to the present disclosure is shown and described in further detail with reference to FIGS. 5-15. FIG. 5 shows a front view of the PVM subsystem. FIG. 6 shows a side view of the PVM subsystem. FIG. 7 shows a side view of the dual CV's and the valves of the PVM subsystem. FIG. 8 shows a top view of the PVM subsystem. FIG. 9 shows a longitudinal cross-section of the metal plate comprising the gas lines of the PVM subsystem. FIGS. 10A and 10B show a transverse cross-section of the metal plate. FIGS. 11A-11F show the base plate of the PVM subsystem in further detail. FIGS. 12A-12F show various views of the heater plates of the PVM subsystem. FIGS. 13A-13C show various views of the thermal interface of the PVM subsystem. FIGS. 14A-14C show the enclosure of the PVM subsystem. FIGS. 15A-15C show the cooling system of the PVM subsystem. Throughout the drawings, the dimensions of some of the components are exaggerated for illustrative purposes.

FIG. 1 shows an example of a substrate processing system 100 (hereinafter the system 100) according to the present disclosure. The system 100 comprises a plurality of sources 102 of process gases; a first set of mass flow controllers (MFCs) 104; a second set of MFCs 106; a plurality of heated PVM subsystems 108-1, 108-2, 108-3, and 108-4 (collectively the PVM subsystems 108); a plurality of processing chambers 110-1, 110-2, 110-3, and 110-4 (collectively the processing chambers 110); a cooling subsystem 112, and a system controller 114. While four PVM subsystems 108 and four processing chambers 110 are shown for example only, in general, the system 100 can comprise N PVM subsystems 108 connected to N processing chambers 110, respectively, where N is an integer greater than 1. Each of the processing chambers 110 comprises a respective showerhead 109-1, 109-2, 109-3, and 109-4 (collectively the showerheads 109). Additional components associated with each of the processing chambers 110 are shown and described with reference to FIG. 3.

In the example of the system 100 shown, the first processing chamber 110-1 and the first PVM subsystem 108-1 are configured to perform a first process, and each of the other processing chambers 110-2, 110-3, 110-4 and each of the other PVM subsystems 108-2, 108-3, 108-4 are configured to perform a second process that is different than the first process as explained below with reference to FIG. 4A. Accordingly, the first PVM subsystem 108-1 is configured differently than each of the other PVM subsystems 108-2, 108-3, and 108-4. Further, the first set of MFCs 104 may be configured differently than the second set of MFCs 106.

The sources 102 supply the process gases (e.g., reactants, inert gases, and precursors). The first set of MFCs 104 comprises MFCs for controlling flow of the process gases supplied to a first processing chamber 110-1. The second set of MFCs 106 comprises MFCs for controlling flow of the process gases supplied to second, third, and fourth processing chambers 110-2, 110-3, 110-4 (hereinafter the other processing chambers 110).

Each PVM subsystem 108 comprises a plurality of charge volumes (CVs), actuating valves, gas lines, and heaters, which are shown and described in detail with reference to FIGS. 5-15. Briefly, each PVM subsystem 108 supplies process gases to the respective processing chamber 110 via the respective showerhead 109 at a predetermined temperature and pressure and in a predetermined sequence. The system controller 114 controls the heaters of the PVM subsystems 108 to supply the process gases at the predetermined temperature. The system controller 114 controls the actuating valves of the PVM subsystems 108 to supply the process gases at the predetermined pressure and in the predetermined sequence.

The cooling subsystem 112 supplies compressed dry air or any other suitable gas to the PVM subsystems 108 prior to performing maintenance as shown and described in detail with reference to FIGS. 15A-15C. The system controller 114 controls the components of the system 100.

FIG. 2 collectively shows the first and second sets of MFCs 104, 106 and the PVM subsystems 108 in further detail. The MFC's 106 may be similar to or different than the MFC's 104. The following description of the MFC's 104 applies equally to the MFC's 106. The first and second sets of MFCs 104, 106 are hereinafter collectively called the MFCs 104. The MFCs 104 are connected to the first PVM subsystem 108-1. The second, third, and fourth PVM subsystem 108-2, 108-3, 108-4 may be similar to or different than the first PVM subsystem 108-1. The following description of the first PVM subsystem 108-1 applies equally to the second, third, and fourth PVM subsystem 108-2, 108-3, 108-4.

The MFCs 104 comprise a plurality of MFCs 120, 122, 124, 126, 128, 130, 132, and 134 and comprise respective valves 121, 123, 125, 127, 129, 131, 133, and 135. The MFCs 120 and 122 receive an inert, nonreactive gas (e.g., gas A) from one of the sources 102. The MFCs 120 and 122 control the flow of the inert gas to the first PVM subsystem 108-1 via the respective valves 121, 123. The MFCs 124 and 126 receive a first reactant (e.g., gas B) from one of the sources 102. The MFCs 124 and 126 control the flow of the first reactant to the first PVM subsystem 108-1 via the respective valves 125, 127. The MFCs 120, 122, 124, and 126 are arranged in a gas box 140.

The MFC 128 and a corresponding valve 129 are arranged in the gas box 140 and control the flow of a precursor (e.g., gas C). In some examples, the MFC 128 and a corresponding valve 129 may be arranged in a separate heated gas box. For example, the precursor may be supplied by one of the sources 102 or may be a solid precursor supplied by the heated gas box. The heated gas box converts the solid precursor into a gaseous state. The MFC 128 also receives the inert gas such (e.g., gas A) from one of the sources 102. The MFC 128 controls flow of the precursor mixed with the inert gas via the valve 129 to the first PVM subsystem 108-1.

The MFCs 130, 132, 134 and corresponding valves 131, 133, 135 are arranged in the gas box 140. The MFC 130 receives a second reactant (e.g., gas D) from one of the sources 102. The MFC 130 controls the flow of the second reactant to the first PVM subsystem 108-1 via the corresponding valve 131. The MFCs 132 and 134 receive the inert gas (e.g., gas A) from one of the sources 102. The MFCs 132 and 134 control the flow of the inert gas to the first PVM subsystem 108-1 via the respective valves 133 and 135.

The first PVM subsystem 108-1 comprises a plurality of CVs 170, 172, 174, 176, 178, 180, 182, and 184. Inlets of the CVs 170, 172, 174, 176, 178, 180, 182, and 184 are connected to the valves 121, 123, 125, 127, 129, 131, 133, and 135 via respective manifolds 171, 173, 175, 177, 179, 181, 183, and 185. The CVs 170, 172, 174, 176, 178, 180, 182, and 184 receive the process gases from the MFCs 120, 122, 124, 126, 128, 130, 132, and 134, through the valves 121, 123, 125, 127, 129, 131, 133, and 135 via the manifolds 171, 173, 175, 177, 179, 181, 183, and 185, respectively.

The first PVM subsystem 108-1 comprises valves 190, 192, 194, 196, 198, 200, 202, and 204. The valves 190, 192, 194, 196, 198, 200, 202, and 204 are connected to outlets of the CVs 170, 172, 174, 176, 178, 180, 182, and 184, respectively. The valves 190, 192, 194, 196, 198, 200, 202, and 204 are three port valves. The connections between the CVs 170, 172, 174, 176, 178, 180, 182, and 184 and the valves 190, 192, 194, 196, 198, 200, 202, and 204 are shown and described in detail with reference to FIGS. 7, 8, and 11A-11F. As shown by arrows in FIG. 11F, in each of the valves 190, 192, 194, 196, 198, 200, 202, and 204, the first port is connected to the third port. Second ports of the valves 190, 192, 194, 196, 198, 200, 202, and 204 are normally closed and are connected to the outlets of the CVs 170, 172, 174, 176, 178, 180, 182, and 184, respectively. The second ports of the valves 190, 192, 194, 196, 198, 200, 202, and 204 are opened for a predetermined duration and in a predetermined sequence by control signals generated by the system controller 114 during processing. An example of a process is described with reference to FIGS. 4A and 4B. Accordingly, one or more process gases flow from the first PVM subsystem 108-1 into the showerhead 109-1 of the first processing chamber 110-1.

FIG. 3 shows additional components associated with each of the processing chambers 110. While the processing chamber 110-1 and the first PVM subsystem 108-1 are described for example only, the description applies equally to all of the other processing chambers 110 (i.e., the processing chambers 110-2, 110-3, 110-4) and the other PVM subsystems 108-2, 108-3, and 108-4.

The processing chamber 110-1 is configured to process a substrate 272 using an ALD process (e.g., using T-ALD). The processing chamber 110-1 comprises a substrate support (e.g., a pedestal) 270. During processing, the substrate 272 is arranged on the pedestal 270. One or more heaters 274 (e.g., a heater array, zone heaters, etc.) may be arranged in the pedestal 270 to heat the substrate 272 during processing. Additionally, one or more temperature sensors 276 are disposed in the pedestal 270 to sense the temperature of the pedestal 270. The system controller 114 receives the temperature of the pedestal 270 sensed by the temperature sensors 276 and controls power supplied to the heaters 274 based on the sensed temperature.

The processing chamber 110-1 further comprises the showerhead 109-1 to introduce and distribute process gases received from the first PVM subsystem 108-1 into the processing chamber 110-1. The showerhead 109-1 includes a stem portion 280 having one end connected to a top plate 281 enclosing the processing chamber 110-1. The first PVM subsystem 108-1 is mounted to the top plate 281 above the showerhead 109-1 using at least two mounting legs 283-1, 283-2.

The first PVM subsystem 108-1 is connected to the stem portion 280 of the showerhead 109-1 via an adapter 282. The adapter 282 includes a first flange 279-1 on a first end and a second flange 279-2 on a second end of the adapter 282. The flanges 279-1, 279-2 are respectively fastened to the bottom of the first PVM subsystem 108-1 and the stem portion 280 of the showerhead 109-1 by fasteners 287-1 through 287-4. The adapter includes bores 285-1, 285-2 (collectively the bores 285) that are in fluid communication with the first PVM subsystem 108-1 and the stem portion 280 of the showerhead 109-1. A base portion 284 of the showerhead 109-1 is generally cylindrical and extends radially outwardly from an opposite end of the stem portion 280 at a location that is spaced from a top surface of the processing chamber 110-1.

A substrate-facing surface of the base portion 284 of the showerhead 109-1 comprises a faceplate 286. The faceplate 286 comprises a plurality of outlets or features (e.g., slots or through holes) 288. The outlets 288 of the faceplate 286 are in fluid communication with the first PVM subsystem 108-1 through the bores 285 of the adapter 282. The process gases flow from the first PVM subsystem 108-1 through the bores 285 and the outlets 288 into the processing chamber 110-1. Additionally, while not shown, the showerhead 109-1 also comprises one or more heaters. The showerhead 109-1 comprises one or more temperature sensors 290 to sense the temperature of the showerhead 109-1. The system controller 114 receives the temperature of the showerhead 109-1 sensed by the temperature sensors 290 and controls power supplied to the one or more heaters based on the sensed temperature.

An actuator 292 is operable to move the pedestal 270 vertically relative to the showerhead 109-1, which is stationary. By vertically moving the pedestal 270 relative to the showerhead 109-1, a gap between the showerhead 109-1 and the pedestal 270 (and therefore a gap between the substrate 272 and the faceplate 286 of the showerhead 109-1) can be varied. The gap can be varied dynamically during a process or between processes performed on the substrate 272. During processing, the faceplate 286 of the showerhead 109-2 is closer to the pedestal 270 than shown.

A valve 294 is connected to an exhaust port of the processing chamber 110-1 and to the vacuum pump 296. The vacuum pump 296 maintains sub-atmospheric pressure inside the processing chamber 110-1 during substrate processing. The valve 294 and the vacuum pump 296 are used to control pressure in the processing chamber 110-2 and to evacuate exhaust gases and reactants from the processing chamber 110-1. The system controller 114 controls these additional components associated with the processing chamber 110-1.

FIG. 4A shows an example of an ALD sequence performed during substrate processing. For example, a first process performed on the substrate in the first processing chamber 110-1 includes depositing a nucleation film on the substrate. A first ALD sequence for the first process includes supplying a dose of gases B and D, followed by purge using gas A, followed by a dose of gases C and A, which is followed by purge using gas A. The first ALD sequence can be generally stated as supplying a first dose of one or more reactants, followed by a first purge step performed using an inert gas, followed by supplying a second dose of a combination of a precursor and the inert gas, followed by performing a second purge step using the inert gas. The system controller 114 repetitively performs the first ALD sequence by controlling the valves 190-204 in the first PVM subsystem 108-1.

For example, a second process performed on the substrates in each of the other processing chambers 110-2, 110-3, and 110-4 includes depositing a bulk metal on the substrates. A second ALD sequence for the second process includes supplying a dose of gas B, followed by purge using gas A, followed by a dose of gases C and A, which is followed by purge using gas A, as shown at 300. The second ALD sequence can be generally stated as supplying a first dose of a reactant, followed by a first purge step performed using an inert gas, followed by supplying a second dose of a combination of a precursor and the inert gas, followed by performing a second purge step using the inert gas. The system controller 114 repetitively performs the second ALD sequence in each of the processing chambers 110-2, 110-3, and 110-4 by controlling the valves in the second, third, and fourth PVM subsystems 108-2, 108-3, and 108-4, respectively.

Typically, during a dose step, the pressure and flow of a reactant (e.g., gas B) from a CV decay rapidly. This problem is solved by using two CVs (and respective MFCs) as shown in FIG. 2 at 174, 176 in the first PVM subsystem 108-1.

As shown at 302 in FIG. 4A, using multiple (e.g., at least two) CVs at each of the processing chambers 110 (i.e., in each of the PVM subsystems 108) for supplying a series of pulses of the reactant (e.g., gas B) can extend the dose time with high flow beyond the pressure decay time. For example, as shown at 302, a second subsequent pulse of the reactant (e.g., gas B) from a second CV (e.g., 176) with high flow is supplied before a first preceding pulse supplied from a first CV (e.g., 174) decays (i.e., before the pressure of the reactant in the first pulse decreases below a threshold).

The timing of supplying the second pulse of the reactant relative to the first pulse of the reactant can be predetermined. For example, the timing can be empirically determined for ALD sequences used in different processes. The system controller 114 can be programmed to control the valves associated with the first and second CVs of the reactant in the PVM subsystem 108 based on the predetermined timing.

Further, the extended dose of the reactant (e.g., gas B) can be delivered as a series of gas B−gas A pulses. For example, the ALD sequence can be M×[N×(gas B−gas A)−gas C−gas A], where N can be any number of gas B−gas A pulses, with each gas B dose being at least two gas B pulses as shown at 302, and where M can be any number of [N×(gas B−gas A)−gas C−gas A] ALD cycles. Typically, hundreds of ALD cycles are performed in series to deposit a film on the substrate. Using a dual pulse dose of the reactant (e.g., gas B) followed by a purge step using an inert gas (e.g., gas A) to sweep away byproducts of the reaction can help drive the ALD reactions to completion faster than using a single uninterrupted reactant (e.g., gas B) dose.

Furthermore, as shown in an example of two ALD sequences at 300 in FIG. 4A, the delay between first and second inert gas purge steps in an arbitrary sequence of ALD cycles can be unequal. For example, two successive inert gas pulses can be separated by a dose of a precursor (e.g., gas C) or by a dose of a reactant (e.g., gas B). In the example shown at 300, the inert gas pulses A1 and A2 in a first ALD sequence are separated by a dose of the precursor (e.g., gas C), and the inert gas pulse A2 of the first ALD sequence and the next inert gas pulse A1 of the subsequent second ALD sequence are separated by a dose of gas B. As shown in the example, a first time period between the A1 and A2 pulses of the first ALD sequence is different than a second time period between the A2 pulse of the first ALD sequence and the next inert gas pulse A1 of the subsequent second ALD sequence.

Accordingly, for ALD sequences with multiple inert gas purge steps, a separate (i.e., independent) CV is used to supply the inert gas (e.g., gas A) in each purge step. Using separate inert gas CVs ensures that each inert gas CV gets equal charge time for each purge step and that the inert gas CVs provide equal starting pressure and flow for the inert gas for the first and second purge steps in ALD sequence. Specifically, a first inert gas CV is used to supply the inert gas pulse A1 in the first purge step, and a second inert gas CV is used to supply the inert gas pulse A2 in the second purge step that follows the first purge step. This enables equal inert gas flow during each purge step (i.e., in each of the inert gas pulses A1 and A2). Using dual inert gas CVs provides equal starting pressure and flow for the inert gas for the first and second purge steps in ALD sequence.

Accordingly, in FIG. 2, each of the PVM subsystems 108-1, 108-2, 108-3, and 108-4 includes two CVs (170, 172) to supply the inert gas (e.g., gas A). Of the pair of CVs, a first CV (e.g., 170) is used during a first purge step, and a second CV (e.g., 172) is used during a subsequent second purge step in each ALD cycle.

In FIG. 2, the first PVM subsystem 108-1 includes an additional and a separate pair of inert gas CVs 182, 184. These CVs 182, 184 supply the inert gas in purge steps that follow a dose of a second reactant (e.g., gas D). The CV 180 that supplies the second reactant (e.g., gas D) and the corresponding inert gas CVs 182, 184 are separate from the CV 178 that supplies the precursor (e.g., gas C) and the corresponding inert gas CVs 170, 172 since the second reactant (e.g., gas D) may be chemically incompatible with the precursor (e.g., gas C supplied). The inert gas CVs 182, 184 are alternately used for supplying the inert gas in successive purge steps that follow the dose of the second reactant (e.g., gas D).

FIG. 4B shows a method 350 for performing ALD on the substrate in a processing chamber using multiple dose pulses and using multiple inert gas charge volumes according to the present disclosure. For example, the system controller 114 shown in FIG. 1 performs the method 350. The term control in the following description of the method 350 refers to the system controller 114.

At 352, control begins an ALD sequence by supplying a first pulse of a reactant from a first CV of a PVM subsystem to a showerhead of a processing chamber (i.e., a processing module or a PM) in a first dose step of the ALD sequence. At 354, in the first dose step, control supplies a second pulse of the reactant from a second CV of the PVM subsystem to the showerhead of the PM before the first pulse decays (i.e., before the pressure of the reactant in the first pulse decreases to less than or equal to a predetermined threshold). At 356, control supplies an inert gas from a third CV of the PVM subsystem to the showerhead of the PM in a first purge step of the ALD sequence that follows the first dose step of the ALD sequence.

At 358, control determines whether to repeat the first dose step and the first purge step of the ALD sequence. Control returns to 352 if the ALD sequence requires repeating the first dose step and the first purge step of the ALD sequence. Control proceeds to 360 if the first dose step and the first purge step of the ALD sequence is not to be repeated (e.g., after repeating the first dose step and the first purge step of the ALD sequence N times, where N is a positive integer).

At 360, control supplies a precursor from a fourth CV of the PVM subsystem to the showerhead of the PM in a second dose step of the ALD sequence. At 362, control supplies the inert gas from a fifth CV of the PVM subsystem to the showerhead of the PM in a second purge step of the ALD sequence. At 364, control determines if the ALD sequence is to be repeated. Control returns to 352 if the ALD sequence is to be repeated. Control ends if the ALD sequence is not to be repeated (e.g., after repeating the ALD sequence M times, where M is a positive integer).

The design of the PVM subsystems 108 and the heating and cooling of the PVM subsystems 108 is now described in detail. Throughout the following description, for example only, eight primary CVs and five secondary CVs are used to describe the design and operation of the PVM subsystems 108. In some PVM subsystems such as 108-2, 108-3, 108-4 and others (not shown), fewer or additional number of primary and secondary CVs may be used. In some PVM subsystems, the secondary CVs may be omitted.

In general, the PVM subsystems described below may include N primary CVs, where N is an integer greater than 1, and may include M secondary CVs, where M is an integer greater than or equal to zero. Regardless of the number of primary and secondary CVs, the design and principles of operation of the heaters and cooling features shown and described below with reference to FIGS. 5-15 apply equally to other configurations of the PVM subsystems.

Throughout the following description, reference is made to three axes: a first axis that is horizontal, a second axis that is horizontal and perpendicular to the first axis, and a third axis that is vertical and perpendicular to both the first and second axes. The first, second, and third axes respectively correspond to the X, Y, and Z axes used in solid geometry.

FIGS. 5 and 6 show an example of a PVM subsystem 400 (which is similar to the PVM subsystems 108) according to the present disclosure. FIG. 5 shows a front view of the PVM subsystem 400 along the first and third axes. FIG. 6 shows a side view of the PVM subsystem 400 along the second and third axes. The PVM subsystem 400 is enclosed in an enclosure, which is shown and described in detail with reference to FIGS. 14A-14C. The enclosure is omitted in FIGS. 5 and 6 to illustrate the design and components of the PVM subsystem 400. Unless specified otherwise, the components of the PVM subsystem 400 are made of a metal, an alloy, or a material that is a good conductor of heat.

The PVM subsystem 400 is mounted on a showerhead 420 (which is similar to the showerheads 109) by at least two mounting legs 422-1 and 422-2 (collectively the mounting legs 422). The height of the mounting legs 422 may be adjustable. The PVM subsystem 400 is connected to the showerhead 420 via an adapter 424.

The PVM subsystem 400 comprises a base plate 402 arranged in a horizontal plane defined by the first and second axes. The base plate 402 is shown and described in detail with reference to FIGS. 11A-11F. Briefly, the base plate 402 is rectangular with the longer side being parallel to the first axis. The base plate 402 is made of a metal such as aluminum, stainless steel (SST), or other suitable material that is a good conductor of heat.

A first set of CVs 404-1, 404-2, . . . , and 404-8 (collectively the CVs 404) having a first capacity are arranged adjacent to each other on the base plate 402 in a first row parallel the first axis. The CVs 404 store process gases. The CVs 404 are made of SST or other suitable material. The CVs 404 are generally cylindrical but may be of any other shape. Each of the CVs 404 includes an inlet and an outlet near a base portion (shown and described below with reference to FIG. 7). The inlets and outlets of the CVs 404 are connected to the base plate 402 (see FIGS. 7 and 11A-11F for details). Each of the CVs 404 has the same predetermined height and the same first predetermined volume (i.e., the first capacity). The CVs 404 extend vertically from the base plate 402 along the third axis.

A plurality of valves 406-1, 406-2, . . . , and 406-8 (collectively the valves 406) are arranged adjacent to each other on the base plate 402 in a second row parallel to the first axis. The valves 406 are aligned with the base portions of the respective CVs 404 along the second axis. The first row of the CVs 404 and the second row of the valves 406 are parallel to each other. The valves 406 are three-port valves. The ports of the valves 406 that are connected to the base plate 402 as explained in detail with reference to FIGS. 11A-11F. Briefly, the first and third ports of each of the valves 406 are normally open and are connected to each other. The valves 406 are interconnected via inserts in the base plate 402, which are shown and described in detail with reference to FIGS. 11A-11F. The second ports of the valves 406 are normally closed and are respectively connected to the outlets of the CVs 404. The second ports of the valves 406 are controlled by the system controller 114 to control the flow of the process gases from the CVs 404 to the showerhead 420. As shown and described below with reference to FIGS. 11A-11F, the outputs of the valves 406 are connected through the base plate 402 and the adapter 424 to the showerhead 420.

A metal plate or a metal block 410 is arranged vertically and perpendicularly to the base plate 402 along the third axis. For example, the metal plate 410 may include a weldment formed by welding together multiple machined components so as to provide the various features of the metal plate 410 described below. The metal plate 410 is shown and described in detail with reference to FIGS. 8-10. Briefly, the metal plate 410 is rectangular with the shorter side being parallel to the first axis and the longer side (i.e., height) being parallel to the third axis. The metal plate 410 comprises a plurality of vertical trenches 414 (visible in FIGS. 10A and 10B) along the height of the metal plate 410. A first set of gas lines (not visible in this view, shown in FIGS. 8-10) having inlets 418-1, 418-2, . . . , and 418-10 (collectively the inlets 418) are disposed in the trenches 414. The inlets 418 are connected to respective manifolds (e.g., elements 171-185 shown in FIG. 2).

As explained in detail with reference to FIGS. 11A-11F, two outermost inlets 418-1 and 418-10 and corresponding gas lines are respectively connected to the first port of the first valve 406-1 and the third port of the eighth valve 406-8 via the base plate 402. The inlets 418-1 and 418-10 and corresponding gas lines supply an inert, non-reactant gas (e.g., gas A) at a relatively low flow rate (called a trickle) of through the valves 406 and the showerhead 420 to the processing chamber (not shown).

Additionally, one or more heating elements, collectively called a third heater (not visible in this view, shown in FIGS. 8-10), are disposed parallel to the first set of gas lines in the metal plate 410 along the height of the metal plate 410. The third heater heats the process gases in the first set of gas lines in the metal plate 410.

Distal ends of the first set of gas lines at the bottom of the metal plate 410 are connected to a second set of gas lines 430 (shown in detail in FIG. 8). The gas lines 430 extend towards the base plate 402 parallel to the second axis (i.e., perpendicular to the first set of gas lines). The gas lines 430 lie in the same horizontal plane in which the base plate 402 lies. As shown in FIG. 8, a first subset of the gas lines 430 is connected directly to the base plate 402. A second subset of the gas lines 430 is connected to the base plate 402 through a second set of CVs 440 (as shown in further detail FIG. 8).

The CVs 440 have a second capacity that is greater than the first capacity of the CVs 404. The CVs 440 have the same predetermined height as that of the CVs 404. The CVs 440 have the same second predetermined volume (i.e., the second capacity) that is greater than the first predetermined volume (i.e., the first capacity) of the CVs 404. Each of the CVs 440 has an inlet and an outlet (shown in FIG. 7). First portions of the second subset of the gas lines 430 (between the distal ends of the first set of gas lines and the CVs 440) are connected to the inlets of the CVs 440. The outlets of the CVs 440 are connected to second portions of the second subset of the gas lines 430 (between the CVs 440 and the base plate 402). Distal ends of the second portions of the second subset of the gas lines 430 are connected to the base plate 402.

The inlets 418, the first set of gas lines, the second set of gas lines 430, the second set of CVs 440, the first set of CVs 404, the base plate 402, and the valves 406 are in fluid communication with each other. The process gases flow from the inlets 418, through the first set of gas lines, through the second set of gas lines 430, through the second set of CVs 440, through the first set of CVs 404, through the base plate 402, through the valves 406, and through the adapter 424 to the showerhead 420 as shown by arrows in FIG. 6.

The PVM subsystem 400 further comprises first and second heaters (also called bottom and top heaters) shown as heater plates 450 and 452, respectively. The heater plate 450 and the heater plate 452 include heating elements and are shown in further detail in FIGS. 12A-12F. Briefly, the heater plate 450 is attached to the bottom of the base plate 402. The heater plate 450 is parallel to the base plate 402. The heater plate 450 extends beyond the base plate 402 along the second axis and is attached to the bottom of the metal plate 410. As shown in FIGS. 14A-14C, to provide thermal insulation, an air gap is maintained between the heater plate 450 and a base panel of the enclosure that surrounds and encloses the PVM subsystem 400.

The heater plate 452 is arranged above the top ends of the CVs 404 and 440. Although the CVs 404 and 440 have the same height, due to manufacturing variations in the heater plate 452, the CVs 404, 440 and other associated components (e.g., base plate 402, mounting hardware, etc.), the top ends of the CVs 404 and 440 may not lie in the same horizontal plane. As a result, the heater plate 452 may not uniformly contact the top ends of the CVs 404, 440 and may not uniformly heat the process gases in the CVs 404, 440.

To uniformly heat the top ends of the CVs 404, 440, a thermal interface 454 is interposed (i.e., sandwiched) between the heater plate 452 and the top ends of the CVs 404, 440. For example, the thermal interface 454 may include thermally conducting material that is less rigid than a metal. For example, the thermal interface 454 may include graphite. When pressed by tightening of the mounting hardware used to mount the heater plate 452, the compressed thermal interface 454 accommodates the manufacturing variations in the heater plate 452, the CVs 404, 440, and the mounting hardware. The compressed thermal interface 454 improves thermal contact and heat conduction between the heater plate 452 and the top ends of the CVs 404, 440. Accordingly, the process gases in the CVs 404, 440 can be uniformly heated by the heater plate 452 regardless of the manufacturing variations in the bottom surface of the heater plate 452, the top surfaces of the CVs 404 and 440, the base plate 402, and the mounting hardware.

FIG. 7 shows a side view of the CVs 404 and 440. The CV 440 has an inlet 460 that is connected to the first portion of one of the gas lines 430. The CV 440 has an outlet 462 that is connected to the second portion of the one of the gas lines 430. The second portion of the one of the gas lines 430 is connected to the base plate 402. As shown in FIGS. 11A-11F, the base plate 402 includes inserts or blocks (hereinafter called the gas channeling blocks) that provide gas flow paths or channels within the base plate 402. The gas flow paths are shown in FIG. 7 by dotted lines at 470, 472. The CV 404 has an inlet 480 that is connected to the first portion of one of the gas lines 430 via a first gas flow path 470. The CV 440 has an outlet 462 that is connected to the second port (shown by “2”) of the corresponding valve 406 via a second gas flow path 472. Gas flow from the gas line 430 through the CVs 440, 404 and the base plate 402 to the valve 406 is shown by arrows.

FIG. 8 shows a top view of the PVM subsystem 400 according to the present disclosure. In this view, all of the second set of gas lines 430, which are not visible in FIGS. 5 and 6, are shown as elements 430-1, 430-2, . . . , and 430-10 (collectively the second set of gas lines 430). In addition, all of the second set of CVs 440, which are not visible in FIGS. 5 and 6, are shown as elements 440-1, 440-2, . . . , and 440-5 (collectively the second set of CVs 440). The gas lines 430 connect to the CVs 440 and to the base plate 402 as shown. The connections between the gas lines 430 and the CVs 440 and the base plate 402 are already described above and are therefore not repeated for brevity.

Further, the metal plate 410 comprises a plurality of heating elements 490-1, 490-2, and 490-3 (collectively the heating elements 490). The heating elements 490 form the third heater disposed in the metal plate 410. Therefore, the metal plate 410 is also called a heater block 410. All other elements, which are identified by reference numerals that are already described above, are not described again for brevity. A longitudinal cross-section A-A of the metal plate 410 and the heating elements 490 taken along the third axis is shown in FIG. 9, which shows the metal plate 410, the heating elements 490, and the first set of gas lines disposed in the metal plate 410 in further detail. A longitudinal cross-section B-B of the valves 406 and the base plate 402 taken along the third axis is shown in FIG. 11F.

FIG. 9 shows the longitudinal cross-section of the metal plate 410 of the PVM subsystem 400. In this view, the first set of gas lines, which are not visible is FIGS. 5-8 are shown as 492-1, 492-2, . . . , and 492-10 (collectively the first set of gas lines 492). The gas lines 492 are disposed in respective trenches 414 (shown in FIGS. 10A and 10B). A cover (shown in FIGS. 10A and 10B) is fastened to an inner, CV-facing side of the metal plate 410 to secure the gas lines 492 in the respective trenches 414. An arrow shows the direction of gas flow through the first set of gas lines 492.

Further, the three heating elements 490 of the third heater are disposed in the metal plate 410 between three pairs of the gas lines 492. For example, the first heating element 490-1 is disposed between the gas lines 492-3 and 492-4; the second heating element 490-2 is disposed between the gas lines 492-5 and 492-6; and the third heating element 490-3 is disposed between the gas lines 492-7 and 492-8. The heating elements 490 are disposed in slots (shown in FIGS. 10A and 10B) provided in the metal plate 410. The heating elements 490 heat the process gases in the gas lines 492.

For example only, the third heater is shown as including three heating elements 490. Alternatively, any number of heating elements 490 can be used. For example, only two heating elements 490 can be used. For example, four, five, six, seven, eight, or nine heating elements 490 can be used. Further, the lengths of the heating elements 490 need not be equal. Furthermore, the lengths of the heating elements 490 need not be about half of the length of the gas lines 492 as shown (i.e., the lengths can be shorter or longer than the length shown). Any combination of the number of heating elements 490 and lengths of the heating elements 490 can be used.

In addition, at least two heat sensors (e.g., thermocouples) 494-1, 494-2 (collectively the heat sensors 494) are disposed in the metal plate 410. The heat sensors 494 can be located anywhere on the metal plate 410. The system controller 114 controls the power supplied to the heating elements 490 based on the temperature of the metal plate 410 sensed by the heat sensors 494. At least two heat sensors 494 are used so that one heat sensor 494 is operational if the other heat sensor 494 fails.

FIGS. 10A and 10B show a transverse cross-section of the metal plate 410 of the PVM subsystem 400. FIG. 10A shows the transverse cross-section of the metal plate 410 with the gas lines 492 and the heating elements 490. FIG. 10A also shows a cover 496 that is fastened to the CV-facing side of the metal plate 410 to secure the gas lines 492 in the respective trenches 414.

FIG. 10B shows the transverse cross-section of the metal plate 410 without the gas lines 492, the heating elements 490, and the cover 496. FIG. 10B shows the trenches 414-1, 414-2, . . . , and 414-8 (collectively the trenches 414) in which the gas lines 492-2, 492-2, . . . , and 492-9 are respectively disposed. The gas lines 492-1 and 492-10 are supported by the side panels of the enclosure that encloses the PVM subsystem 400 and are secured by the cover 496. Additionally, FIG. 10B shows an example of a plurality of bores 416-1, 416-2, and 416-3 (collectively the bores 416) in which the heating elements 490-1, 490-2, and 490-3 are respectively disposed in the metal plate 410.

FIGS. 11A-11F show the base plate 402 of the PVM subsystem 400 in further detail. FIGS. 11A and 11B show a top view of the base plate 402 including the gas channeling blocks (described below) that provide the gas flow paths in the base plate 402. FIGS. 11C and 11D respectively show top and longitudinal side views of the base plate 402 without the gas channeling blocks and show only the slots in the base plate 402 in which the gas channeling blocks are inserted. FIG. 11E shows the gas channeling blocks in detail. FIG. 11F shows a cross-section of the base plate 402 taken along the line D-D in FIG. 11A with the addition of the valves 406 (and along the line B-B in FIG. 8).

In FIGS. 11A and 11B, elements 504 (described below) are shown with a fill so as to differentiate elements 504 from neighboring elements 502. FIG. 11B is the same as FIG. 11A except that the locations for mounting the CVs 404 and the valves 406 to the base plate 402 are shown by dotted lines to illustrate how the CVs 404 and the valves 406 align with the gas channeling blocks on the base plate 402. Dotted lines are used so as to not obscure the gas channeling blocks. Each of the valves 406 includes a first port 560, a second port 562, and a third port 564. The connections of the CVs 404 and the valves 406 to the various gas flow paths provide by the gas channeling blocks in the base plate 402 are described below in detail.

In FIGS. 11A-11D, the base plate 402 comprises first gas channeling blocks 502-1, 502-2, . . . , and 502-8 (collectively the first gas channeling blocks 502). The base plate 402 comprises second gas channeling blocks 504-1, 504-2, . . . , and 504-6 (collectively the second gas channeling blocks 504). The base plate 402 comprises first slots 506-1, 506-2, . . . , and 506-8 (collectively the first slots 506) that extend longitudinally through the base plate 402 parallel to the second axis. The first slots 506 are essentially trenches formed between the two sides 402-1 and 402-2 of the base plate 402 and ridges 508-1, 508-2, . . . , and 508-7 (collectively the ridges 508) in the base plate 402. The ridges 508 extend vertically upwards from the bottom of the base plate 402 parallel to the third axis. The first gas channeling blocks 502-1, 502-2, . . . , and 502-8 are inserted into the slots 506-1, 506-2, . . . , and 506-8, respectively. The second gas channeling blocks 504-1, 504-2, 504-3, 504-4, 504-5, and 504-6 are arranged on top of the ridges 508-1, 508-2, 508-4, 508-5, 508-6, and 508-7, respectively. The first and second gas channeling blocks 502, 504 are shown and described below in further detail with reference to FIG. 11E.

The third ridge 508-3 is longer (i.e., has a greater height) than the other ridges 508. The tops of the two sides 402-1 and 402-2 of the base plate 402 and the top of the third ridge 508-3 lie in the same plane defined by the first and second axes. Two bores 550-1 and 550-2 are drilled through the third ridge 508-3. The bores 550-1, 550-2 are in fluid communication with the showerhead 420 through corresponding holes in the heater plate 450 (shown in FIGS. 12 and 14) and the bores in the adapter 424 E.g., see the bores 285 in the adapter 282 shown in FIG. 3).

As shown in FIG. 11D, the ridges 508 other than the third ridge 508-3 (i.e., the other ridges 508) are shorter than the third ridge 508-3. The other ridges 508 are of equal height. The height of the other ridges 508 is such that when the second gas channeling blocks 504 are arranged on the tops of the other ridges 508, the combined height of one of the other ridges 508 and one of the second gas channeling blocks 504 is equal to the height of the third ridge 508-3. That is, when the second gas channeling blocks 504 are arranged on the tops of the other ridges 508, the tops of the second gas channeling blocks 504 are level with (i.e., in the same plane as) the top of the third ridge 508-3 and the tops of the two sides 402-1 and 402-2 of the base plate 402. When the first gas channeling blocks 502 are inserted in the slots 506, the tops of the first and second gas channeling blocks 502, 504, the top of the third ridge 508-3, and the tops of the two sides 402-1 and 402-2 of the base plate 402 lie in the same plane (hereinafter called the top surface of the base plate 402 for convenience).

The gas lines 430-2, 430-2, . . . , and 430-9 are connected to the base plate 402 using connectors 509-1, 509-2, . . . , and 509-8, respectively (collectively the connectors 509). The connectors 509-1, 509-2, . . . , and 509-8 include openings 510-1, 510-2, . . . and 510-8 (collectively the openings 510), respectively. The openings 510 of the connectors 509 are in the same plane as the top surface of the base plate 402. The openings 510 of the connectors 509 open upwards in the direction of the third axis. The openings 510 are in fluid communication with the respective gas lines 430-2 through 430-9. The openings 510 mate with and are in fluid communication with the inlets of the CVs 404 when the CVs 404 are installed on the top surface of the base plate 402. The openings 510 fluidly connect the respective gas lines 430 to the inlets of the CVs 404. The process gases from the gas lines 430-2 through 430-9 enter into the CVs 404 through the openings 510 and through the respective inlets of the CVs 404.

As described above, the gas lines 430-1 and 430-10 supply a small volume of the inert gas at a low flow rate (called a trickle) through the base plate 402, the valves 406, and the showerhead 420 into the processing chamber. The trickle prevents backflow of gases from the processing chamber to the PVM subsystem 400. The gas lines 430-1 and 430-10 connect directly to the base plate 402. The base plate 402 includes first and second bores 540-1, 540-2 on the two sides 402-1, 402-2 of the base plate 402. The first and second bores 540-1, 540-2 extend horizontally through the base plate 402 along the second axis as shown by dotted lines. The gas lines 430-1 and 430-10 connect to (or are inserted into) first ends of the first and second bores 540-1, 540-2. The base plate 402 includes third and fourth bores 542-1 and 542-2 (see FIG. 11D) having first ends respectively connected to second ends of the first and second bores 540-1, 540-2. The third and fourth bores 542-1 and 542-2 extend vertically through the base plate 402 along the third axis. The second ends of the third and fourth bores 542-1 and 542-2 respectively provide openings 544-1, 544-2 at the top surface of the base plate 402.

Before describing the remaining features of the base plate 402 shown in FIG. 11A, the first and second gas channeling blocks 502, 504 are described in detail with reference to FIG. 11E. FIG. 11E shows one of the first gas channeling blocks 502 and one of the second gas channeling blocks 504 in greater detail. The first gas channeling block 502 comprises a first rectangular portion 520, a tubular portion 522, and a second rectangular portion 524. The first rectangular portion 520 is connected to the tubular portion 522. The tubular portion 522 is connected to the second rectangular portion 524.

The first rectangular portion 520 includes a first bore 526. The first bore 526 extends horizontally through the first rectangular portion 520 along the second axis. A first end of the first bore 526 at a first end of the first rectangular portion 520 is fluidly connected to a first end of the tubular portion 522. A second end of the first bore 526 extends vertically upwards through the first rectangular portion 520 along the third axis and provides an opening 528 on a top surface of the first rectangular portion 520. Accordingly, in FIG. 11A, the first gas channeling blocks 502-1, 502-2, . . . , and 502-8 include first openings 528-1, 528-2, . . . , and 528-8 (collectively the first openings 528), respectively. The first openings 528 of the first gas channeling blocks 502 are in fluid communication with the respective outlets of the CVs 404 when the CVs 404 are installed on the top surface of the base plate 402.

In FIG. 11E, a first end of the second rectangular portion 524 of the first gas channeling block 502 is connected to a second end of the tubular portion 522. The second rectangular portion 524 includes a second bore 530. The second bore 530 extends through the second rectangular portion 524 along the second axis. A first end of the second bore 530 at the first end of the second rectangular portion 524 is connected to the second end of the tubular portion 522. A second end of the second bore 530 extends vertically upwards through the second rectangular portion 524 along the third axis and provides an opening 532 on a top surface of the second rectangular portion 524. Accordingly, in FIG. 11A, the first gas channeling blocks 502-1, 502-2, . . . , and 502-8 include second openings 530-1, 530-2, . . . , and 530-8 (collectively the first openings 530), respectively. The second openings 530 of the first gas channeling blocks 502 are in fluid communication with the second ports 562 of respective valves 406 when the valves 406 are installed on the top surface of the base plate 402.

In each of the first gas channeling blocks 502, the first opening 528, the first bore 526 in the first rectangular portion 520, the tubular portion 522, the second bore 530 in the second rectangular portion 524, and the second opening 532 are in fluid communication with each other. The first rectangular portion 520 and the tubular portion 522 extend horizontally along the second axis. The second rectangular portion 524 extends vertically downwards from the tubular portion 522 towards the bottom of the base plate 402 along the third axis. The first and second openings 528, 532 lie in the same plane as that of the top surface of the base plate 402. The first and second openings 528, 532 open in the same vertically upward direction relative to the top surface of the base plate 402 along the third axis.

In each of the first gas channeling blocks 502, the first and second rectangular portions 520, 524 have the same width as the width of the slot 506 (measured along the first axis). The length (i.e., height) of the second rectangular portion 524 is equal to the depth (i.e., height) of the slot 506 (both measured along the third axis). The height of the first rectangular portion 520 is less than the height of the slot 506 (both measured along the third axis).

Each of the second gas channeling blocks 504 is rectangular with the longer side being parallel to the top surface of the base plate 402 and the first axis. The second gas channeling block 504 includes a bore 570 that extends along the length of the second gas channeling block 504 parallel to the first axis. The two ends of the bore 570 extend vertically upwards through the second gas channeling block 504 along the third axis and provide first and second openings 572, 574 on the top surface of the second gas channeling block 504. Accordingly, in FIG. 11A, the second gas channeling blocks 504-1, 504-2, . . . , and 504-6 include first openings 572-1, 572-2, . . . , and 572-6 (collectively the first openings 572), respectively. The second gas channeling blocks 504-1, 504-2, . . . , and 504-6 include second openings 574-1, 572-4, . . . , and 574-6 (collectively the first openings 574), respectively. The first openings 572 of the second gas channeling blocks 504 are in fluid communication with the third ports 564 of respective valves 406 when the valves 406 are installed on the top surface of the base plate 402. The second openings 574 of the second gas channeling blocks 504 are in fluid communication with the first ports 560 of respective valves 406 when the valves 406 are installed on the top surface of the base plate 402.

The second openings 532 of the first gas channeling blocks 502 and the first and second openings 572, 574 of the second gas channeling blocks 504 are collinear and parallel to the first axis. The openings 532, 572, 574; the ports 560, 562, 564 of the valves 406; and the openings of the bores 550-1 and 550-2 at the top of the third ridge 508-3 are collinear and parallel to the first axis.

In FIG. 11F, when the valves 406 are installed on the base plate 402, the first port 560 of the first valve 406-1 is in fluid communication with the opening 544-1 on the top surface of the base plate 402. Accordingly, the gas line 430-1, which is in fluid communication with the opening 544-1 through the bores 540-1 and 542-1, is in fluid communication with the first port 560 of the first valve 406-1. The third port 564 of the eighth valve 406-8 is in fluid communication with the opening 544-2 on the top surface of the base plate 402. Accordingly, the gas line 430-10, which is in fluid communication with the opening 544-2 through the bores 540-2 and 542-2, is in fluid communication with the third port 564 of the eighth valve 406-8.

The first port 560 of the first valve 406-1 is normally in fluid communication with the third port 564 of the first valve 406-1. The third port 564 of the first valve 406-1 is in fluid communication with the first port 560 of the second valve 406-2 via the second gas channeling block 504-1. The first port 560 of the second valve 406-2 is normally in fluid communication with the third port 564 of the second valve 406-2. The third port 564 of the second valve 406-2 is in fluid communication with the first port 560 of the third valve 406-3 via the second gas channeling block 504-2. The first port 560 of the third valve 406-3 is normally in fluid communication with the third port 564 of the third valve 406-3. The third port 564 of the third valve 406-3 is normally in fluid communication with the opening of the bore 550-1 at the top of the third ridge 508-3. Accordingly, as shown by arrows, the inert gas (i.e., the trickle described above) from the gas line 430-1 is normally supplied through the first and third ports 560, 564 of the first, second, and third valves 406-1, 406-2, 406-3 and through the bore 550-1 to the showerhead 420.

The third port 564 of the eighth valve 406-8 is normally in fluid communication with the first port 560 of the eighth valve 406-8. The first port 560 of the eighth valve 406-8 is in fluid communication with the third port 564 of the seventh valve 406-7 via the second gas channeling block 504-6. The third port 564 of the seventh valve 406-7 is normally in fluid communication with the first port 560 of the seventh valve 406-7. The first port 560 of the seventh valve 406-7 is in fluid communication with the third port 564 of the sixth valve 406-6 via the second gas channeling block 504-5. The third port 564 of the sixth valve 406-6 is normally in fluid communication with the first port 560 of the sixth valve 406-6. The first port 560 of the sixth valve 406-6 is in fluid communication with the third port 564 of the fifth valve 406-5 via the second gas channeling block 504-4. The third port 564 of the fifth valve 406-5 is normally in fluid communication with the first port 560 of the fifth valve 406-5. The first port 560 of the fifth valve 406-5 is in fluid communication with the third port 564 of the fourth valve 406-4 via the second gas channeling block 504-3. The third port 564 of the fourth valve 406-4 is normally in fluid communication with the first port 560 of the fourth valve 406-4. The first port 560 of the fourth valve 406-4 is normally in fluid communication with the opening of the bore 550-2 at the top of the third ridge 508-3. Accordingly, as shown by arrows, the inert gas (i.e., the trickle described above) from the gas line 430-10 is normally supplied through the third and first ports 564, 560 of the eighth, seventh, sixth, fifth, and fourth valves 406-8, 406-7, 406-6, 406-5, 406-4 and through the bore 550-2 to the showerhead 420.

The second ports 562 of the valves 406 are in fluid communication with the second openings 532 of the respective first gas channeling blocks 502. The second openings 532 are in fluid communication with the outlets of the respective CVs 404 via the first openings 528 of the first gas channeling blocks 502. The system controller 114 controls the second ports 562 of the valves 406 to supply the process gases from the CVs 404 to the showerhead 420 as explained above with reference to FIGS. 1-4B. When the second port 462 of any of the valves 406 is opened, the opened second port 562 of the valve 406 is in fluid communication with the first and third ports 560, 564 of that valve 406. Accordingly, by controlling the second ports 462 of the valves 406, one or more of the process gases (e.g., reactants, precursors, and purge gases) from the respective CVs 404 flow through the bore 550-1 and/or 550-2 to the showerhead 420.

At least two heat sensors 580-1, 580-2 (collectively the heat sensors 580) are disposed in the base plate 402. For example, the heat sensors 580 (e.g., thermocouples) may be disposed proximate to the bores bore 550-1, 550-2. Alternatively, the heat sensors 580 may be disposed at any other suitable locations in the base plate 402. The system controller 114 controls the power supplied to the heating elements (shown and described below with reference to FIGS. 12A-12F) in the heater plate 450 based on the temperature of the base plate 402 sensed by the heat sensors 580. At least two heat sensors 580 are used so that one heat sensor 580 is operational if the other heat sensor 580 fails.

The heating of the process gases in the PVM subsystem 400 according to the present disclosure is now described. Thereafter, the rapid cooling of the PVM subsystem 400 according to the present disclosure is explained. In the PVM subsystem 400, the gas lines 492 are heated by the heating elements 490 in the metal plate 410 as already described above with reference to FIGS. 8-10B. Accordingly, the process gases in the gas lines 492 are heated by the heating elements 490. Thereafter, the process gases flow through the gas lines 430, into the CVs 440, 404, though the gas flow paths in the base plate 402, though the valves 406, and subsequently to the showerhead 420.

The heater plate 450 heats the gas lines 430, the bottom portions of the CVs 440, 404, the base plate 402, and the valves 406. The heater plate 452 heats the top portions of the CVs 440, 404. Accordingly, the process gases in the gas lines 430, the CVs 440, 404, the base plate 402, and the valves 406 are heated by the heater plates 450, 452.

The system controller 114 controls the heating elements 490 and heating elements in the heater plates 450, 452 (shown and described below with reference to FIGS. 12A-12F) to uniformly heat the process gases throughout the PVM subsystem 400. The system controller 114 controls the heating elements 490 by sensing temperatures proximate to the heating elements 490 using the heat sensors 494 associated with the heating elements 490. The system controller 114 controls the heating elements of the heater plate 450 by sensing temperatures proximate to the heater plate 450 using the heat sensors 580 associated with the heater plate 450. The system controller 114 controls the heating elements of the heater plate 452 by sensing temperatures proximate to the heater plate 452 using heat sensors associated with the heater plate 452.

FIGS. 12A-12F show various views of the heater plates 450 and 452 of the PVM subsystem 400 according to the present disclosure. FIGS. 12A-12C show the views of the heater plates 450 and 452 with heating elements. FIGS. 12D-12F show the views of the heater plates 450 and 452 without the heating elements. FIGS. 12A and 12D show top views of the heater plates 450 and 452. FIGS. 12B and 12E show cross-sectional side views of the heater plates 450 and 452 along the longer sides of the heater plates 450 and 452. FIGS. 12C and 12F show cross-sectional side views of the heater plates 450 and 452 along the shorter sides of the heater plates 450 and 452.

The heater plates 450 and 452 are rectangular and have the same dimensions. As shown in FIG. 5, the base plate 402 is arranged on the heater plate 450, and the heater plate 452 is arranged on top of the CVs 404, 440. The heater plate 450 includes a cutout 596. The cutout 596 is shown by dotted lines because the heater plate 452 does not include the cutout 596. The adapter 424 of the showerhead 420 is connected to the base plate 402 through the cutout 596. The remainder of the description of the heater plate 450 applies equally to the heater plate 452.

The heater plate 450 includes two heating elements 590-1 and 590-2 (collectively the heating elements 590). The heating elements 590 are similar to the heating elements 490 disposed in the metal plate 410. The heater plate 450 includes two bores 592-1 and 592-2 (collectively the bores 592) along the length of the heater plate 450. The heating elements 590-1 and 590-2 are inserted into the bores 592-1 and 592-2, respectively. The heating elements 590 and the bores 592 are parallel to the first axis. Cross-sections of the heater plate 450 along the line A-A parallel to the first axis are shown with and without the heating elements 590 in FIGS. 12B and 12E. Cross-sections of the heater plate 450 along the line B-B parallel to the second axis are shown with and without the heating elements 590 in FIGS. 12C and 12F.

For example only, the heater plate 450 is shown as including two heating elements 590. Alternatively, any number of heating elements 590 can be used. For example, only one heating element 590 can be used. For example, more than two heating elements 590 can be used. Further, the lengths of the heating elements 490 need not be equal. Furthermore, the lengths of the heating elements 490 need not be equal to the length of the heater plate 450 as shown. Any combination of the number of heating elements 590 and lengths of the heating elements 590 can be used. Further, the combination in the heater plate 450 may be different than the combination in the heater plate 452.

In addition, at least two heat sensors (e.g., thermocouples) 594-1, 594-2 (collectively the heat sensors 594) are disposed in the heater plates 450, 452. The heat sensors 594 can be located anywhere in the heater plate 450. The system controller 114 controls the power supplied to the heating elements 590 based on the temperature of the heater plate 450 sensed by the heat sensors 594. At least two heat sensors 594 are used so that one heat sensor 594 is operational if the other heat sensor 594 fails.

FIGS. 13A-13C show various views of the thermal interface 454 of the PVM subsystem 400 according to the present disclosure. FIG. 13A shows a top view of the thermal interface 454. FIG. 13B shows a cross-sectional side view of the thermal interface 454 along the longer side of the thermal interface 454. FIG. 13B shows a cross-sectional side view of the thermal interface 454 along the shorter side of the thermal interface 454.

As described before with reference to FIG. 5, the thermal interface 454 is disposed (i.e., sandwiched) between the heater plate 452 and the top ends of the CVs 404, 440. For example, the thermal interface 454 may include material such as graphite. When pressed by tightening of the mounting hardware used to mount the heater plate 452, the thermal interface 454 compresses against the bottom surface of the heater plate 452 and the top surfaces of the CVs 404, 440. By compressing against the bottom surface of the heater plate 452 and top surfaces of the CVs 404, 440, the thermal interface 454 improves the thermal contact and heat conduction between the heater plate 452 and the top ends of the CVs 404, 440. The thermal interface 454 improves the thermal contact and heat conduction regardless of manufacturing variations in the bottom surface of the heater plate 452 and top surfaces of the CVs 404, 440. Accordingly, the process gases in the CVs 404, 440 can be uniformly heated by the heater plate 452. Cross-sections of the thermal interface 454 along the line A-A parallel to the first axis and along the line B-B parallel to the second axis are shown in FIGS. 13B and 13C, respectively.

FIGS. 14A-14C show an example of an enclosure 600 of the PVM subsystem 400 according to the present disclosure. FIG. 14A shows the enclosure 600. FIG. 14B shows a top view of a bottom panel 602 of the enclosure 600 on which the heater plate 450 is arranged as shown in FIG. 14C. FIG. 14C shows a side cross-sectional view of the bottom panel 602 of the enclosure 600 with the heater plate 450 arranged thereon.

FIG. 14A shows the enclosure 600 comprising six rectangular surfaces: one each of top and bottom surfaces (identified by numbers 1 and 2, respectively), and front and back surfaces (identified by numbers 3 and 4, respectively), and two side surfaces (identified by numbers 5 and 6, respectively). Accordingly, the enclosure 600 may comprise six rectangular panels, one panel for each of the six surfaces. Alternatively, the enclosure 600 can comprise only four panels: one each of top and bottom panels and two side panels, with each side panel covering two adjacent surfaces (e.g., (3,5) and (4,6) or (3,6) and (4,5)). For example, the panels can be made of a sheet metal. The inside of each of the panels includes a lining of a layer of a thermally insulating material. An example of the layer of the thermally insulating material is shown at 630 in FIG. 14C. Examples of the thermally insulating material include fiber glass. Other thermally insulating materials can be used instead.

In the following description, the bottom panel 602, a front panel 604, and a side panel 606 are referenced. The side panel 606 can cover surface 5 or 3 of the enclosure 600. The bottom panel 602 includes a cutout 610 that aligns with the cutout 596 in the heater plate 450. The adapter 424 passes through the cutouts 610 and 596 to connect the shower head 420 to the base plate 402. The front panel 604 includes a plate and an inlet (collectively shown at 620) for dispensing compressed dry air or other suitable cooling gas or gases into the PVM subsystem 400 as described below in detail with reference to FIGS. 15A-15C. The side panel 606 includes an outlet 621. The compressed dry air or other suitable cooling gas or gases injected in to the enclosure through the inlet exit the enclosure 600 via the outlet 621.

FIG. 14B shows the top view of the bottom panel 602. The heater plate 450 is disposed on and is parallel to the bottom panel 602 as shown in FIG. 14C. The longer side of the bottom panel 602 is parallel to the first axis. The shorter side of the bottom panel 602 is parallel to the second axis. The inside of the bottom panel 602 (i.e., the surface of the bottom panel 602 facing the heater plate 450) includes the layer 630 of the thermally insulating material. Similar layers of the thermally insulating material line the insides of the other panels of the enclosure 600.

In FIGS. 14B and 14C, a plurality of spacers 612-1, 612-2, 612-3, 612-4 (collectively the spacers 612) are arranged between the heater plate 450 and the bottom panel 602. The spacers 612 provide an air gap between the heater plate 450 and the bottom panel 602. The air gap (exaggerated for illustrative purposes) provides additional thermal insulation. The thermal insulation provided by the layer 630 of the thermally insulating material and the air gap reduce heat loss, which increases the efficiency of the heating elements 490 in the metal plate 410 and the heating elements 590 in the heater plates 450, 452.

FIGS. 15A-15C show an example of a cooling system (element 620 shown in FIG. 14A) of the PVM subsystem 400. The cooling system includes a plate 622 and an inlet 624. FIG. 15A shows a front view of the cooling system with the plate 622 and the inlet 624 mounted to the front panel 604 of the enclosure 600. FIG. 15B shows a side view of the front panel 604 with the plate 622 and the inlet 624 mounted to the front panel 604. FIG. 15C shows the plate 622 in further detail.

For example, the plate 622 includes three portions 622-1, 622-2, and 622-3. The plate 622 may be a single piece. Alternatively, the three portions of the plate 622 may be joined together using fasteners (or may be welded together) to form the plate 622. For example only, each of the three portions is shown as being rectangular but can be of any other shape instead. In the example shown, the first portion 622-1 is wider (i.e., longer along the first axis) than each of the second and third portions 622-2, 622-3. Accordingly, the plate 622 may have a shape of the letter “T” with the first portion 622-1 forming the top horizontal portion of the letter “T” and the second and third portions 622-2, 622-3 together forming the vertical portion of the letter “T.” Alternatively, all of the three portions of the plate 622 may be of the same size.

In the side view shown in FIG. 15B, the first portion 622-1 extends vertically downwards (i.e., towards the bottom panel 602 of the enclosure 600) parallel to the third axis. The first portion 622-1 is attached to the front panel 604 using two or more fasteners 626-1, 626-2 (collectively the fasteners 626). Alternatively, the first portion 622-1 may be welded to the front panel 604.

The second portion 622-2 extends perpendicularly (or at another angle) inwards (i.e., towards the center of the enclosure 600) from a bottom end of the first portion 622-1. The third portion 622-3 extends vertically (or at another angle) downwards (i.e., towards the bottom panel 602 of the enclosure 600) from a bottom end of the second portion 622-2.

The third portion 626-3 includes a plurality of holes 628-1, 628-2, 628-3, 628-4 (collectively the holes 628). While four holes 628 are shown for example only, the third portion 626-3 may include fewer or more number of holes 628. While the holes 628 are shown as being of the same size and shape, the holes 628 can be of different sizes and shapes that are suitable to distribute the compressed air or gas evenly throughout the enclosure 600.

In some examples, the first portion 622-1 may be omitted and the second portion 622-2 may be fastened or welded directly to the front panel 604. In this example, the second portion 622-1 may be of the same size and shape as the third portion 622-3. Alternatively, the second portion 622-1 may be of a different size and/or shape than the third portion 622-3.

The inlet 624 is attached to the front panel 604 such that the inlet 624 is aligned with the center of the third portion 622-3 of the plate 622. The inlet 624 is connected to a source of pressurized dry air or other suitable gas or gases (e.g., one of the sources 102 or a separate source) that can be used to rapidly cool the PVM subsystem 400 before performing maintenance. For example, the inlet 624 can include a nozzle (or any other suitable device) that is pneumatically controlled by the system controller 114. The compressed air or gas is injected via the inlet 624 into the enclosure 600. The compressed air or gas is distributed or dispersed across (i.e., throughout) the enclosure 600 (e.g., over the CVs 404 etc.) via the holes 628 as shown by arrows. In some examples, while not shown and while unnecessary, the holes 628 may be drilled in the third portion 622-3 such that the holes 628 can direct the compressed air or gas in specific directions into the enclosure 600 (shown by the arrows). In some examples, any other device or artifact (e.g., a cone) may be used with the inlet 624 instead of the plate 622 to uniformly distribute the compressed air or gas throughout the enclosure 600.

The system controller 114 can be used to inject the compressed air or gas through the inlet 624 before maintenance is to be performed on the PVM subsystem 400. The compressed air or gas rapidly cools the PVM subsystem 400, which allows the maintenance to be performed without waiting for the PVM subsystem 400 to cool by convection. The compressed air or gas injected into the enclosure 600 from the inlet 624 exits the enclosure 600 from the outlet 621. In some examples, multiple elements 620 may be used. Locations of the elements 620, 621 can be different than those shown.

The foregoing description is merely illustrative in nature and is not intended to limit the disclosure, its application, or uses. The broad teachings of the disclosure can be implemented in a variety of forms. Therefore, while this disclosure includes particular examples, the true scope of the disclosure should not be so limited since other modifications will become apparent upon a study of the drawings, the specification, and the following claims.

It should be understood that one or more steps within a method may be executed in different order (or concurrently) without altering the principles of the present disclosure. Further, although each of the embodiments is described above as having certain features, any one or more of those features described with respect to any embodiment of the disclosure can be implemented in and/or combined with features of any of the other embodiments, even if that combination is not explicitly described. In other words, the described embodiments are not mutually exclusive, and permutations of one or more embodiments with one another remain within the scope of this disclosure.

Spatial and functional relationships between elements (for example, between modules, circuit elements, semiconductor layers, etc.) are described using various terms, including “connected,” “engaged,” “coupled,” “adjacent,” “next to,” “on top of,” “above,” “below,” and “disposed.” Unless explicitly described as being “direct,” when a relationship between first and second elements is described in the above disclosure, that relationship can be a direct relationship where no other intervening elements are present between the first and second elements, but can also be an indirect relationship where one or more intervening elements are present (either spatially or functionally) between the first and second elements. As used herein, the phrase at least one of A, B, and C should be construed to mean a logical (A OR B OR C), using a non-exclusive logical OR, and should not be construed to mean “at least one of A, at least one of B, and at least one of C.”

In some implementations, a controller is part of a system, which may be part of the above-described examples. Such systems can comprise semiconductor processing equipment, including a processing tool or tools, chamber or chambers, a platform or platforms for processing, and/or specific processing components (a wafer pedestal, a gas flow system, etc.). These systems may be integrated with electronics for controlling their operation before, during, and after processing of a semiconductor wafer or substrate. The electronics may be referred to as the “controller,” which may control various components or subparts of the system or systems.

The controller, depending on the processing requirements and/or the type of system, may be programmed to control any of the processes disclosed herein, including the delivery of processing gases, temperature settings (e.g., heating and/or cooling), pressure settings, vacuum settings, power settings, radio frequency (RF) generator settings, RF matching circuit settings, frequency settings, flow rate settings, fluid delivery settings, positional and operation settings, wafer transfers into and out of a tool and other transfer tools and/or load locks connected to or interfaced with a specific system.

Broadly speaking, the controller may be defined as electronics having various integrated circuits, logic, memory, and/or software that receive instructions, issue instructions, control operation, enable cleaning operations, enable endpoint measurements, and the like. The integrated circuits may include chips in the form of firmware that store program instructions, digital signal processors (DSPs), chips defined as application specific integrated circuits (ASICs), and/or one or more microprocessors, or microcontrollers that execute program instructions (e.g., software). Program instructions may be instructions communicated to the controller in the form of various individual settings (or program files), defining operational parameters for carrying out a particular process on or for a semiconductor wafer or to a system. The operational parameters may, in some embodiments, be part of a recipe defined by process engineers to accomplish one or more processing steps during the fabrication of one or more layers, materials, metals, oxides, silicon, silicon dioxide, surfaces, circuits, and/or dies of a wafer.

The controller, in some implementations, may be a part of or coupled to a computer that is integrated with the system, coupled to the system, otherwise networked to the system, or a combination thereof. For example, the controller may be in the “cloud” or all or a part of a fab host computer system, which can allow for remote access of the wafer processing. The computer may enable remote access to the system to monitor current progress of fabrication operations, examine a history of past fabrication operations, examine trends or performance metrics from a plurality of fabrication operations, to change parameters of current processing, to set processing steps to follow a current processing, or to start a new process.

In some examples, a remote computer (e.g. a server) can provide process recipes to a system over a network, which may include a local network or the Internet. The remote computer may include a user interface that enables entry or programming of parameters and/or settings, which are then communicated to the system from the remote computer. In some examples, the controller receives instructions in the form of data, which specify parameters for each of the processing steps to be performed during one or more operations. It should be understood that the parameters may be specific to the type of process to be performed and the type of tool that the controller is configured to interface with or control.

Thus as described above, the controller may be distributed, such as by comprising one or more discrete controllers that are networked together and working towards a common purpose, such as the processes and controls described herein. An example of a distributed controller for such purposes would be one or more integrated circuits on a chamber in communication with one or more integrated circuits located remotely (such as at the platform level or as part of a remote computer) that combine to control a process on the chamber.

Without limitation, example systems may include a plasma etch chamber or module, a deposition chamber or module, a spin-rinse chamber or module, a metal plating chamber or module, a clean chamber or module, a bevel edge etch chamber or module, a physical vapor deposition (PVD) chamber or module, a chemical vapor deposition (CVD) chamber or module, an atomic layer deposition (ALD) chamber or module, an atomic layer etch (ALE) chamber or module, an ion implantation chamber or module, a track chamber or module, and any other semiconductor processing systems that may be associated or used in the fabrication and/or manufacturing of semiconductor wafers.

As noted above, depending on the process step or steps to be performed by the tool, the controller might communicate with one or more of other tool circuits or modules, other tool components, cluster tools, other tool interfaces, adjacent tools, neighboring tools, tools located throughout a factory, a main computer, another controller, or tools used in material transport that bring containers of wafers to and from tool locations and/or load ports in a semiconductor manufacturing factory.

What is claimed is:

1. A system comprising:
first and second canisters configured to supply a reactant to a processing chamber during a dose step of an atomic layer deposition (ALD) sequence;
first and second valves configured to connect the first and second canisters to the processing chamber, respectively; and
a controller configured to:
supply a first pulse of the reactant from the first canister to the processing chamber during the dose step of the ALD sequence by activating the first valve; and
supply a second pulse of the reactant from the second canister to the processing chamber during the dose step of the ALD sequence by activating the second valve.

2. The system of claim 1 further comprising:
a third canister configured to supply a purge gas to the processing chamber during a purge step of the ALD sequence; and
a third valve configured to connect the third canister to the processing chamber;
wherein the controller is configured to supply a third pulse of the purge gas from the third canister to the processing chamber during the purge step of the ALD sequence by activating the third valve, and
wherein the third pulse is supplied after supplying the second pulse of the reactant in the dose step.

3. A system comprising:
first and second canisters configured to supply a purge gas to a processing chamber during purge steps of an atomic layer deposition (ALD) sequence;
first and second valves configured to connect the first and second canisters to the processing chamber, respectively; and
a controller configured to:
supply a first pulse of the purge gas from the first canister to the processing chamber during a first purge step of the ALD sequence by activating the first valve; and
supply a second pulse of the purge gas from the second canister to the processing chamber during a second purge step of the ALD sequence by activating the second valve,
wherein the second purge step follows the first purge step in the ALD sequence.

4. The system of claim 3 further comprising:
a third canister configured to supply a second gas to the processing chamber during a dose step of the ALD sequence, the second gas including a reactant or a precursor; and
a third valve configured to connect the third canister to the processing chamber;
wherein the controller is configured to supply a third pulse of the second gas from the third canister to the processing chamber during the dose step of the ALD sequence by activating the third valve; and
wherein the third pulse is supplied after supplying the first pulse of the purge gas in the first purge step and before supplying the second pulse of the purge gas in the second purge step.

5. A system comprising:
first and second canisters configured to supply a reactant to a processing chamber during a dose step of an atomic layer deposition (ALD) sequence;
a third canister configured to supply a purge gas to the processing chamber during a purge step of the ALD sequence;
first, second, and third valves configured to connect the first, second, and third canisters to the processing chamber, respectively; and
a controller configured to:
a) supply a first pulse of the reactant from the first canister to the processing chamber during the dose step of the ALD sequence by activating the first valve; and
b) supply a second pulse of the reactant from the second canister to the processing chamber during the dose step of the ALD sequence by activating the second valve after the first pulse;
c) supply a third pulse of the purge gas from the third canister to the processing chamber during the purge step of the ALD sequence by activating the third valve following the second pulse of the reactant in the dose step; and
d) repeat a), b), and c) N times, where N is a positive integer.

6. The system of claim 5 further comprising:
a fourth canister configured to supply a precursor to the processing chamber during a second dose step of the ALD sequence;
a fifth canister configured to supply the purge gas to the processing chamber during a second purge step of the ALD sequence; and
fourth and fifth valves configured to connect the fourth and fifth canisters to the processing chamber, respectively;
wherein the controller is configured to:
e) supply a fourth pulse of the precursor from the fourth canister to the processing chamber during the second dose step of the ALD sequence by activating the fourth valve following d); and
f) supply a fifth pulse of the purge gas from the fifth canister to the processing chamber during the second purge step of the ALD sequence by activating the fifth valve following e).

7. The system of claim 6 wherein the controller is configured to repeat f) M times, where M is a positive integer.

8. A system comprising:
first and second canisters configured to supply a reactant to a processing chamber during a first dose step of an atomic layer deposition (ALD) sequence;
a third canister configured to supply a precursor to the processing chamber during a second dose step of the ALD sequence;
fourth and fifth canisters configured to supply a purge gas to the processing chamber during purge steps of the ALD sequence;
first, second, third, fourth, and fifth valves configured to connect the first, second, third, fourth, and fifth canisters to the processing chamber, respectively; and
a controller configured to:
a) supply a first pulse of the reactant from the first canister to the processing chamber during the first dose step of the ALD sequence by activating the first valve;
b) supply a second pulse of the reactant from the second canister to the processing chamber during the first dose step of the ALD sequence by activating the second valve after the first pulse;
c) supply a third pulse of the purge gas from the fourth canister to the processing chamber during a first purge step of the ALD sequence by activating the fourth valve following the second pulse of the reactant in the first dose step;
d) supply a fourth pulse of the precursor from the third canister to the processing chamber during the second dose step of the ALD sequence by activating the third valve following the third pulse of the purge gas in the first purge step; and
e) supply a fifth pulse of the purge gas from the fifth canister to the processing chamber during a second purge step of the ALD sequence by activating the fifth valve following the fourth pulse of the precursor in the second dose step.

9. The system of claim 8 wherein the controller is configured to:
f) repeat a), b), and c) N times before performing d) and e);
g) perform d) and e) after f); and
repeat g) M times, where M is a positive integer.

10. A system comprising:
a plurality of gas lines arranged in slots in a metal plate;
a first heater disposed adjacent to the slots in the metal plate;
a plurality of canisters arranged on a base plate and connected to the gas lines; and
a plurality of valves arranged on the base plate to connect the canisters to a showerhead of a processing chamber.

11. The system of claim 10 further comprising a second heater attached to the base plate.

12. The system of claim 10 further comprising a second heater arranged above the canisters.

13. The system of claim 12 further comprising a layer of a thermally conducting material disposed between the second heater and the canisters.

14. The system of claim 10 further comprising:
a second heater attached to the base plate;
a third heater arranged above the canisters; and
a layer of a thermally conducting material disposed between the third heater and the canisters.

15. The system of claim 10 wherein the canisters are of the same size and shape.

16. The system of claim 10 further comprising a second plurality of canisters connected between the gas lines and the plurality of canisters.

17. The system of claim 16 wherein the second plurality of canisters have a different storage capacity than the plurality of canisters.

18. The system of claim 16 further comprising:
a second heater attached to the base plate;
a third heater arranged above the plurality of canisters and the second plurality of canisters; and
a layer of a thermally conducting material disposed between the third heater and the plurality of canisters and the second plurality of canisters.

19. The system of claim 18 further comprising:
a third plate that includes the second heater, that extends from the base plate, and that is connected to the metal plate;
wherein the second plurality of canisters is arranged on the extended portion of the third plate.

20. An enclosure comprising the system of claim 14 mounted on the processing chamber, wherein inner walls of the enclosure include a second layer of a thermally insulating material.

21. The enclosure of claim 20 further comprising:
an inlet mounted to a first side of the enclosure to supply a pressurized gas into the enclosure; and
an outlet on a second side of the enclosure to let out the pressurized gas from the enclosure.

22. The enclosure of claim 20 further comprising a distribution device mounted to the first side inside the enclosure that is aligned with the inlet to distribute the pressurized gas in the enclosure.

23. The enclosure of claim 20 wherein the second heater is attached to a bottom of the base plate and is attached to a base panel of the enclosure using spacers.

24. The system of claim 14 further comprising at least two heat sensors disposed in each of the metal plate, the base plate, and a third plate comprising the third heater.

25. The system of claim 10 wherein the base plate comprises gas channels that connect the gas lines, the canisters, and the valves.

26. The system of claim 10 wherein the base plate comprises a plurality of bores in fluid communication with the valves and the processing chamber.

27. The system of claim 10 further comprising an adapter block connecting the base plate to a showerhead of the processing chamber and including a plurality of bores in fluid communication with the valves and the showerhead.

28. The system of claim 10 wherein the base plate comprises a first plurality of bores in fluid communication with the valves, the system further comprising an adapter block connecting the base plate to a showerhead of the processing chamber and including a second plurality of bores in fluid communication with the first plurality of bores and the showerhead.

29. The system of claim 10 wherein:
the metal plate is perpendicular to the base plate; and
the canisters and the valves are arranged in rows parallel to each other and the metal plate.

30. The system of claim 29 further comprising:
a third plate including the second heater attached to the base plate, wherein the third plate extends from the base plate and is connected to the metal plate;
a second plurality of canisters is arranged on the extended portion of the third plate and is connected to the gas lines and the plurality of canisters.

31. The system of claim 30 further comprising:
a third heater arranged above the plurality of canisters and the second plurality of canisters; and
a layer of a thermally conducting material disposed between the third heater and the plurality of canisters and the second plurality of canisters.

32. The system of claim 30 wherein the second plurality of canisters have a different storage capacity than the plurality of canisters.

33. The system of claim 30 wherein the second plurality of canisters includes fewer number of canisters than the plurality of canisters.
